(19) United States
(12) Patent Application Publication
(10) Pub. No.: US 2023/0100995 A1
(43) Pub. Date: Mar. 30, 2023

(54) HIGH RESOLUTION LATENT IMAGE PROCESSING, CONTRAST ENHANCEMENT AND THERMAL DEVELOPMENT

(71) Applicants: Inpria Corporation, Corvallis, OR (US); Tokyo Electron Limited, Tokyo (JP)

(72) Inventors: Brian J. Cardineau, Corvallis, OR (US); Peter de Schepper, Wijnegem (BE)

(21) Appl. No.: 17/950,685

(22) Filed: Sep. 22, 2022

Related U.S. Application Data
(60) Provisional application No. 63/247,885, filed on Sep. 24, 2021.

(51) Int. Cl. G03F 7/004; G03F 7/36; G03F 7/38

(52) U.S. Cl. CPC G03F 7/0042; G03F 7/36; G03F 7/38

(57) ABSTRACT

Patterning of organometallic radiation sensitive compositions is facilitated using a gaseous form of a contrast enhancing agent, which can include a carboxylic acid, an amide, a sulfonic acid, an alcohol, a diol, a silyl halide, a germanium halide, a tin halide, an amine, a thiol, or a mixture thereof, in which the mixture can be of the same class or different class of compounds. Contact with the contrast enhancing reactive compound is provided after irradiation of the organometallic composition to form a latent image. The contrast enhancing agent can be delivered before or after physical pattern development, and processing with the contrast enhancing agent can involve removal in a thermal process of some or substantially all of the non-irradiated organometallic composition. The contrast enhancing agent can be used in a dry thermal development step. If the contrast enhancing agent is used after a distinct development step, use of the contrast enhancing agent can involve improvement of the pattern quality. Apparatuses for performing processing with contrast enhancing agents are described.

### CROSS REFERENCE TO RELATED APPLICATIONS

This application claims priority to copending U.S. provisional patent application 63/247,885 to Cardineau et al. filed Sep. 24, 2021, entitled “High Resolution Latent Image Processing and Thermal Development,” incorporated herein by reference.

### FIELD OF THE INVENTION

The invention relates to post deposition and irradiation processing of organometallic radiation patterning compositions, which can involve contact with a contrast enhancer and developing a physical image after irradiation. In particular, the invention relates to reactive vapor treatments to improve image contrast with potential facilitation of thermal material removal facilitating pattern development and/or patterning improvement. The invention also pertains to apparatuses for performing the processing.

### BACKGROUND OF THE INVENTION

Semiconductor patterning requires high-performance and high-resolution photoresists to enable smaller and smaller features. Fabrication of semiconductor devices generally involves many iterative processing steps of deposition, patterning, and etching to realize the desired devices. Patterning is generally achieved through the use of lithographic processes. In lithography, aerial patterns of radiation are translated into physical patterns by using a photoresist and a development process.

Efforts to provide further reduction in pattern resolution obtained by photolithography have provided impetus for development of novel photoresist chemistries. In this context, organometallic radiation patternable compositions have been developed. With new chemistries introduced by these compositions, a host of new process capabilities are potentially available to further improve patterning processes.

### SUMMARY OF THE INVENTION

One aspect of the invention pertains to a method for developing an organotin resist with a composition comprising a contrast enhancer, wherein said contrast enhancer can be chosen, for example, from an amine, a silyl halide, an alcohol, an amide, a sulfonic acid, a carboxylic acid, a thiol, tin halide, germanium halide, and mixtures thereof. In some embodiments, the contrast enhancer can be used in combination with gaseous acid halide, HF, HCl, HBr and/or HI, to facilitate reaction. Some water vapor may be desirable in combination with other reactants.

Another aspect of the invention pertains to a method for developing an organotin resist with a contrast enhancer composition comprising trimethylsilyl halide.

Another aspect of the invention pertains to a method for developing an organotin resist with a composition comprising an alkyl group.

In another aspect, the invention pertains to a method for removing material from a patterned substrate after an initial development process wherein the method comprises contacting the patterned substrate to a contrast enhancer in vapor form.

In a first aspect, the invention pertains to a method for enhancing development contrast between irradiated and non-irradiated portions of a radiation sensitive organometallic composition on a substrate surface with a latent image, the method comprising:

contacting the organometallic composition with a reactant gas in an isolated chamber to alter the composition of the irradiated portion, the non-irradiated portion or both, wherein the reactant gas comprises an amide, a sulfonic acid, alcohol, diol, silyl halide, germanium halide, tin halide, amine, or mixtures thereof.

In a second aspect, the invention pertains to a method for modifying a radiation sensitive organometallic composition on a substrate surface with a latent image formed by respective irradiated and non-irradiated portions, the method comprising contacting the organometallic composition with a vapor of a carboxylic acid in an isolation chamber at a partial pressure from about 0.1 Torr to about 50 Torr, at a temperature from about 100° C. to about 250° C., with a flow rate from about 0.1 sccm to about 5000 sccm, at a temperature from about −45° C. to about 250° C. to remove a relative amount of the non-irradiated portion ((initial nonirradiated thickness-final non-irradiated thickness)/initial non-irradiated thickness) wherein the relative amount of the non-irradiated portion removed is at least about 10%, while a relative amount of thickness of the irradiated portion removed ((initial irradiated thickness-final irradiated thickness)/initial irradiated thickness) is no more than one third of the relative amount of non-irradiated portion removed.

In a third aspect, the invention pertains to a method for improving the quality of a patterned structure with a negative pattern corresponding to an irradiated organometallic composition on a substrate surface with non-irradiated organometallic composition substantially removed or with a positive pattern corresponding to non-irradiated organometallic composition on a substrate surface with the irradiated organometallic composition substantially removed, the method comprising:

developing a pattern from a latent image formed by irradiating a radiation sensitive organometallic composition on a substrate surface to form a patterned structure; and

following completion of the development step, contacting the patterned structure with a reactant gas in an isolated chamber to remove scum from the pattern, wherein the reactant gas is selected from water, a carboxylic acid, an amide, a sulfonic acid, alcohol, diol, silyl halide, germanium halide, tin halide, amine, thiol, a hydrogen halide or mixtures thereof.

In a fourth aspect, the invention pertains to a method for dry developing a radiation sensitive organometallic composition having a radiation-patterned latent image on a substrate, the method comprising:

contacting the composition having the latent image with a reactant gas to remove a substantial portion of the non-irradiated regions of the coating, wherein the non-irradiated regions of the coating comprise Sn—C bonds, and the reactant gas comprises an amide, a sulfonic acid, alcohol, diol, silyl halide, germanium halide, tin halide, amine, thiol, or mixtures thereof.

In a fifth aspect, the invention pertains to a method for developing a radiation sensitive organometallic composition having a radiation-patterned latent image on a substrate, the method comprising:

contacting the radiation patterned material with a first reactant gas composition to modify the non-irradiated regions of the coating, wherein the non-irradiated regions of the coating comprise Sn—C bonds, and the first reactant gas composition comprises a carboxylic acid, an amide, a sulfonic acid, an alcohol, a diol, a silyl halide, a germanium halide, a tin halide, an amine, a thiol, or a mixture thereof, to form an initial pattern; and,

contacting the initial pattern with a second reactant gas composition different from the first reactant gas composition to remove a portion of the initial pattern, wherein the second reactant gas composition comprises a carboxylic acid, an amide, a sulfonic acid, an alcohol, a diol, a silyl halide, a germanium halide, a tin halide, an amine, a thiol, or a mixture thereof.

In a sixth aspect, the invention pertains to an apparatus comprising:

an enclosed chamber;

a substrate support within the enclosed chamber, wherein the substrate support is configured to spin a substrate;

a gas supply subsystem comprising a gas source reservoir, a gas spray dispenser having a pluralities of openings distributed to provide gas dispensing directed toward a substrate mounted on the substrate support and over the extent of the substrate surface, a gas flow controller, and gas conduits connecting the gas source reservoir and the gas spray dispenser with the flow through the conduits moderated by the gas flow controller;

a liquid supply subsystem comprising a liquid reservoir, a nozzle, a nozzle support with a translatable arm for positioning the nozzle, a flow controller and tubing providing flow channels between the liquid reservoir and the nozzle, wherein the nozzle support has a configuration to configure the nozzle to deposit liquid on a substrate mounted on the substrate support;

one or more exhausts exiting the chamber; and

a pump.

### BRIEF DESCRIPTION OF THE DRAWINGS

FIG. 1 is a flow chart of latent image processing of a patterned organotin coating via treatment with a contrast enhancer and a dry developer.

FIG. 2 is a flow chart of latent image processing of a patterned organotin coating via treatment with a contrast enhancer after development.

FIG. 3 is a flow chart of latent image processing of a patterned organotin coating using a contrast enhancer as a vapor reactive developer.

FIG. 4 is a schematic view of a process system shown with a vapor delivery system connected to a process chamber.

FIG. 5 is a schematic view of a process system having a showerhead vapor distribution unit.

FIG. 6 is a schematic view of a process system shown with a vapor delivery system and a liquid delivery system connected to a process chamber.

FIG. 7 is a series of plots of coating thickness versus time for irradiated and unirradiated regions of patterned coated substrates subjected to a contrast enhancer under various processing conditions.

### DETAILED DESCRIPTION OF THE INVENTION

Compounds are delivered with dry, i.e., vapor delivery, processes to a substrate with an organometallic patterning composition having a latent image to facilitate physical pattern development. Organometallic photoresists have been developed that provide a high degree of contrast between exposed and unexposed regions. In some embodiments, patterning materials can comprise organotin compositions that form an oxo-hydroxo network with tin-carbon bonds forming radiation sensitive metal-ligand interactions. While the processes and ancillary apparatuses and compositions can be effective more broadly, the discussion focuses primarily on organotin compositions that are of more immediate commercial relevance. This high contrast can be used directly to form physical patterns that can be used to transfer the pattern to a substrate through addition or etchings using the patterned resist as a mask. Nevertheless, process improvements, such as described herein, can provide for efficiencies in patterning and improvements in pattern quality and reduction of pattern defects. In some embodiments, a contrast enhancer compound is used to amplify chemical differences between non-irradiated portions of an organometallic patterning composition and adjacent irradiated regions. A vapor processing step can be desirable to introduce the contrast enhancers and to control the process conditions for the reactions induced by the contrast enhancers. In some embodiments, treatment with the contrast enhancer provides for thermal development of the treated non-irradiated portions through the conversion to compounds that have vapor pressures sufficient for appropriate thermal development of the substrates being patterned. In a continuum of process possibilities, a contrast enhancer can differentially react with the organometallic composition of a latent image to further increase contrast between irradiated and non-irradiated portions of the composition along with possibly removal of non-irradiated material, which if sufficiently removed results in pattern development. Thus, in one limit of the continuum, the contrast enhancement treatment actually results in a dry development process. In the opposite limit of the continuum, the contrast enhancing treatment improves contrast for a subsequent wet or dry development step without significant material removal during the treatment with the contrast enhancing agent. Intermediate degrees of processing are between these limits of the continuum.

In a one-step process, the contrast enhancing reaction and thermal development is performed simultaneously for particularly effective developing, and for these embodiments, the contract enhancer can be referred to as a vapor reactive developer. Thermal development provides an alternative dry development process that avoids plasma generation used for plasma based development. In alternative or additional embodiments, a wet development or a distinct dry development can be used following treatment with a contrast enhancer. A distinct dry development can comprise use of a different reactive gas or the use of a plasma driven process. In additional or further embodiments, the contrast enhancer and/or the thermal development can be applied following a more conventional development process to remove residue for defect reduction. Furthermore, a rinse step can be used following development based on any of these embodiments or intermediate between a development step and a dry scum removal step to reduce the incidence of patterning defects. Organometallic patterning compositions offer great promise for high resolution patterning, especially in the context of EUV patterning, and the reduction of patterning defects is a significant step in process development to allow for the full exploitation of the potential of organometallics.

To summarize, the contrast enhancing gases can be used for development, whether or not they directly result in the removal of non-irradiated organometallic composition, for pattern improvement after completion of development in a separate processing step, or separately for both, distinct steps, generally with different contrast enhancing gas compositions. For development, the contrast enhancing agent can be involved in a continuum of roles from changing composition of non-irradiated organometallic composition to effectively removing substantially all of the non-irradiated organometallic composition in a dry, thermal development, or any degree in between no removal and substantially complete removal. If substantially complete removal of non-irradiated organometallic composition is not achieved, a subsequent step to complete development can be any wet development or any dry development step, which may be thermal or plasma driven. After completion of development to remove substantially all of the non-irradiated organometallic composition, a pattern improvement step can be performed. A wet treatment for pattern improvement can be performed, as described below. In some embodiments, regardless of how the development is performed, contrast enhancing gases can be used in a separate step for pattern improvement in a thermal process. The pattern improvement using contrast enhancing gases is a separate regime for use of these agents. The integration of these processes with other process aspects is explained in the following.

The demand for continued shrinkage of patterned semiconductor devices has driven development of higher performance photoresist materials capable of producing small and high-fidelity features. Photoresists are materials that undergo a chemical change upon irradiation with radiation, It is desirable for such materials to faithfully reproduce the aerial image of radiation as physical and chemical images between irradiated and un-irradiated regions. This chemical image may be developed by removing selected regions of the photoresist by wet or dry methods.

Radiation sources are generally any source of photons (such as visible, ultraviolet, extreme ultraviolet, or x-rays) or ion beams (such as electron beams) that can be directed to form a desired pattern through the use of a photomask or by controllably rastering the radiation source across the photoresist. For state-of-the-art applications, it is generally desirable for device and feature sizes to be as small as possible, and, in general, a direct relationship is exhibited between feature size and the radiation source wavelength. For example, in current state-of-the-art commercial lithographic processing, extreme ultraviolet (EUV) sources having a wavelength of 13.5 nm are used.

Wafer processing generally includes a series of individual processes that the substrate or wafer undergoes from coating/deposition to removal of a pattern mask from the substrate. In some embodiments, the substrate is a semiconductor wafer, such as a silicon wafer with optional surface coatings or other modifications. Additionally, tone-reversal processes may be implemented to invert the tone of the photoresist pattern. In general, wafer processes can include coating, baking, transfer steps, backside and edge-bead rinsing, radiation exposure, development, annealing, and etch, among others, and often with multiple steps of each type. To perform these steps, liquid, plasma, and gas/vapor processes are often used during semiconductor device fabrication. For organometallic photoresists, e.g., organotin compositions, the use of gas/vapor processes can provide useful steps and are described herein in the context of the overall process progression.

Recently, organotin compounds have been shown to be effective EUV photoresists capable of achieving very high resolutions. To enable high resolution patterning, these organotin materials can be deposited as thin films/coatings and possess a high etch contrast in relation to conventional polymer photoresist materials, thus enabling more efficient pattern transfer into the underlying substrate. As described further below, precursors involving hydrolysable ligands can be used for forming the radiation sensitive patterning composition. The organotin deposition can be performed with wet or dry processing, although spin-on organotin resists are currently available commercially from Inpria Corporation (Oregon, USA). Post-irradiation processing described herein is directed to increasing the development contrast through selective reaction with the non-irradiated portions of the photoresist.

Metal oxide hydroxide photoresists, such as organotin photoresists, have been shown to possess excellent properties as photoresists for use in photolithographic patterning. Example metal oxide hydroxide photoresists include hafnium and zirconium oxide hydroxides that have been described in U.S. Pat. No. 9,176,377B2, entitled “Patterned Inorganic Layers, Radiation Based Patterning Compositions And Corresponding Methods” by Stowers et al. and in U.S. Pat. No. 9,281,207B2, entitled “Solution Processible Hardmasks for High Resolution Lithography” by Stowers et al, both of which are incorporated herein by reference. Organotin oxide hydroxide photoresists, in particular, have been shown to achieve high resolution and high sensitivity. Desirable organotin oxide hydroxide photoresists include organotin materials as described in U.S. Pat. No. 9,310,684B2 to Meyers et al. (the '684 patent), entitled “Organometallic Solution Based High Resolution Patterning Compositions,” published U.S. patent application 2016/0116839A1 to Meyers et al., entitled “Organometallic Solution Based High Resolution Patterning Compositions and Corresponding Methods,” and U.S. Pat. No. 10,228,618B2 (hereinafter the '618 patent), entitled “Organotin Oxide Hydroxide Patterning Compositions, Precursors, and Patterning”, all of which are incorporated herein by reference. More details on particular organotin compositions are described below.

While not wanting to be limited by theory, it is believed that during exposure to ionizing radiation, such as EUV photons, UV photons, and ion beams, the Sn—C bonds are cleaved, presumably with the formation of a species with R. The bond cleavage results in volatilization of hydrocarbyl R groups, and the creation of highly reactive Sn sites with unsatisfied coordination numbers. Densification can then occur via crosslinking and/or condensation between Sn sites by reaction with other moieties in the coating, or by reaction with species in the processing environment, for example, water. In this way, the irradiation of the coating to a pattern of radiation creates a latent image with corresponding patterning of the density in the coating wherein the irradiated regions generally are more dense than the non-irradiated regions. In a typical EUV lithography process, following exposure to EUV radiation the coating is exposed to ambient air wherein further reaction with water and/or CO₂ can occur within the irradiated regions of the coating to drive the formation of a condensed network, thereby creating a substantial chemical contrast between irradiated and non-irradiated regions.

To realize the physical image of the chemical contrast, photoresists are typically developed in either a negative-tone process, wherein the non-irradiated material is selectively removed, or in a positive-tone process wherein the irradiated material is selectively removed. Organotin photoresists can operate in either tone. Irradiated regions of organotin oxide hydroxide coatings are generally hydrophilic and are thus soluble in aqueous acids or bases and insoluble in organic solvents; conversely, non-irradiated regions are generally hydrophobic and are thus soluble in organic solvents and insoluble in aqueous acids or bases. Some useful developer compositions for these organotin oxide photoresists have been described in published U.S. Patent Application No. 2020/0326627 to Jiang et al. (hereinafter the '627 application), entitled “Organometallic Photoresist Developer Compositions and Processing Methods”, incorporated herein by reference. Processing described herein addresses contrast enhancers that are designed to increase chemical contrast through preferential reaction with the un-irradiated portion of the coating to render the un-irradiated coating portions more hydrophobic and/or more volatile. In some embodiments, the contrast enhancers can form product coating compositions that have significant volatility so that thermal development can be achieved as a dry development process without invoking plasma assistance in the dry development, which can reduce contrast due to the plasma glow. A one step dry development with simultaneous reaction of the contrast enhancer as a vapor reactive developer can be particularly efficient through providing penetration access as the prior reacted coating is removed. In general, the contrast enhancer can modify the non-irradiated and possibly irradiated organometallic patterning composition, remove a portion of the non-irradiated patterning composition, or substantially completely remove the non-irradiated patterning composition.

The contrast enhancer can also be used after a development step. In this context, the contrast enhancer can be used to improve the pattern quality, such as through removal of scum, i.e., residual patterning material incompletely removed, and the like, which can result in microbridges and other pattern defects can be result in rejection of device-level components due to quality control issues. The use of a vapor contrast enhancer to remove scum and other defects can be used alternatively or in addition to a solution rinse, as described in '627 application, for improving the quality of a negative tone pattern.

Processing with reactive gases to alter irradiated organotin patterning compositions is described in published U.S. patent application 2021/0271170 to Telecky et al. (hereinafter the '170 application), entitled “Process Environment for Inorganic Resist Patterning,” incorporated herein by reference. As described in the '170 application, the reactive gases can be used as contrast enhancers for reactively treating the irradiated organometallic coatings. In some embodiments, the compounds taught in the '170 application can be delivered following irradiation to react with the irradiated portions of the coating to increase hydrophilic character. The reactant gases in the '170 application include CO₂, SO₂, H₂S, CH₃SH, CO, COS, HOOH, NH₃, H₂, O₃, nitrogen oxide, PH₃, SiH₄, CH₄, ethylene oxide or a combination thereof. This processing of the irradiated portions of the coating can be combined with the contrast enhancers described herein generally to react with the non-irradiated portions of the coatings.

It has also been described that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al, entitled “Dry Development of Resists”, incorporated herein by reference. See also, Tan et. al. in published PCT Pat App. WO2020/264158 entitled “Photoresist Development With Halide Chemistries”, incorporated herein by reference. In such dry development processes, development can be achieved by exposing the irradiated substrate to a plasma or a thermal process while flowing a gas comprising a Lewis acid, such as a small molecule R_{y}Zₓ, containing a halide (F, Cl, Br), for example BCl₃, a methyl group or a hydrogen with R being B, Al, Si, C, S, or SO. The Tan publication refers to plasma or thermal development with a hydrogen halide or other halide containing chemistry.

A further dry etching approach is described in published PCT application WO 2022/125388 to Dictus et al. (hereinafter the '388 application), entitled “Photoresist Development with Organic Vapor,” incorporated herein by reference. In the '388 application, carboxylic acid vapors, which may be combined with acid halides HX, X═F, Cl, Br, I, are described for use in a dry development. No examples are presented in the '388 application, and appropriate conditions are not described. The processes in the '388 application are further taught to be useful for cleaning residue from the chamber, where the residue is deposited through the chamber as a by-product of vapor deposition of the resist material. The preferred organic acids in the '388 application are halogenated to increase the acidity. As described herein, appropriate process conditions are described for the differential removal of the non-irradiated material using a carboxylic acid. The '388 application emphasizes all vapor processing.

The current disclosure describes development of organotin coatings by use of contrast enhancers that can selectively react with the non-irradiated regions of the coating to render the selected region more volatile and improve removal of the material. Appropriate choice of contrast enhancer can improve, for example, the removal of the non-irradiated regions by converting the low-density organotin moieties to more volatile low molecular weight species.

In some embodiments, the exposure to a contrast enhancer can be performed during a thermal process, in which case the contrast enhancer can function as a vapor reactive developer. In some embodiments, the thermal process may comprise controlling the temperature of the contrast enhancer before contacting it with the substrate. In other embodiments, the thermal process may comprise controlling the temperature of the substrate during contact with the contrast enhancer. Such thermal processes can generally include cooling or heating, in which cooling can be performed, for example, if the reaction with the contrast enhancer is exothermic and generates significant heat. Specifically, for highly reactive contrast enhancers (i.e., agents that react quickly with the coating) it may be beneficial to cool the substrate during its exposure to the contrast enhancer in order to better control the removal rates and subsequent pattern fidelity. In other embodiments, the thermal process can comprise heating the substrate and/or contrast enhancer in order to improve removal rates. Contract enhancers may be delivered with an inert gas.

To improve the development of an irradiated organotin coating, it can be beneficial to expose the substrate to a contrast enhancer that is capable of selectively reacting with the non-irradiated regions of the coating in order to facilitate removal of that material during development. In some embodiments, the exposure of the coating to a contrast enhancer can be conducted prior to a subsequent developer step. For example, exposure to a contrast enhancer may convert the non-irradiated regions to lower molecular weight and/or more volatile species but without significant immediate removal (volatilization) of that material, which can then be removed in a subsequent development step wherein said regions are substantially removed from the substrate. In other embodiments, the exposure of the coating to a contrast enhancer can be conducted during the development step. For example, exposure of the substrate to a volatizing agent may result in substantial volatilization (i.e., removal and/or development) of the non-irradiated material to afford a physical pattern.

### Patterning Compositions and Coating Formation

In embodiments of particular interest, the organometallic patterning compositions are organotin composition that form oxo-hydroxo networks on the substrate surface. These compositions can be formed using solution coating or vapor deposition approaches, and while oxo-hydroxo solutions can be used for deposition, alternative embodiments involve the use of precursors with hydrolysable ligands that are hydrolyzed during and/or following deposition to form the oxo-hydroxo network. The substrate with the organotin oxo-hydroxo composition optionally can be subject to a post deposition bake to stabilize the material. The coating is patterned using radiation to form a latent image. In the following section, post irradiation processing and pattern development are discussed.

In some embodiments, organometallic radiation sensitive resists have been developed based on alkyl tin compositions, such as alkyltin oxide hydroxide, approximately represented by the formula R_{z}SnO_{(2-z/2-x/2)}(OH)ₓ, where 0<x<3, 0<z≤2, x+z≤4, and R is a hydrocarbyl or organo group forming a carbon bond with the tin atom, generally with the carbon atom being sp³ or sp² hybridized. The z=1 compositions can be of particular interest where the formula reduces to RSnO_{(3/2-x/2)}(OH)ₓ. There can be patterning advantages in using a blend of different R groups in the overall composition, and it can be understood in the above formula that R can represent a plurality of different R groups within a material. Particularly effective forms of these compositions are monoalkytin oxide hydroxide, in which z=1 in the above formula. In particular, R can be a moiety with 1-31 carbon atoms with one or more carbon atoms optionally substituted with one of more heteroatom functional groups, such as groups containing O, N, Si, Ge, Sn, Te, and/or halogen atoms, or an alkyl, or a cycloalkyl further functionalized with a phenyl, or cyano group. In some embodiments, R can comprise ≤10 carbon atoms and can be, for example, methyl, ethyl, propyl, isopropyl, butyl, t-butyl, isobutyl, or t-amyl. The R group can be a linear, branched, (i.e., secondary or tertiary at the metal-bonded carbon atom), or cyclic hydrocarbyl group. Each R group individually and generally has from 1 to 31 carbon atoms with 3 to 31 carbon atoms for the group with a secondary-bonded carbon atom and 4 to 31 carbon atoms for the group with a tertiary-bonded carbon atom. In particular, branched alkyl ligands can be desirable for some patterning compositions where the compound can be represented as R¹R²R³CSn(NR′)₃, where R¹ and R² are independently an alkyl group with 1-10 carbon atoms, and R³ is hydrogen or an alkyl group with 1-10 carbon atoms. As noted below, this representation of alkyl ligand R is similarly applicable to the other embodiments generally with R¹R²R³CSn(X)₃, with X corresponding to the trialkoxide or triamide moieties. In some embodiments R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CH₂CH₃), sec-butyl (R¹ is methyl, R² is —CH₂CH₃, and R³ is hydrogen), neopentyl (R¹ and R² are hydrogen, and R³ is —C(CH₃)₃), cyclohexyl, cyclopentyl, cyclobutyl, and cyclopropyl. Examples of suitable cyclic groups include, for example, 1-adamantyl (—C(CH₂)₃(CH)₃(CH₂)₃ or tricyclo(3.3.1.13,7) decane bonded to the metal at a tertiary carbon) and 2-adamantyl (—CH(CH)₂(CH₂)₄(CH)₂(CH₂) or tricyclo(3.3.1.13,7) decane bonded to the metal at a secondary carbon). In other embodiments, hydrocarbyl groups may include aryl or alkenyl groups, for example, benzyl or allyl, or alkynyl groups. In other embodiments, the hydrocarbyl ligand R may include any group consisting solely of C and H and containing 1-31 carbon atoms. In summary, some examples of suitable alkyl groups bonded to tin include, for example, linear or branched alkyl (i-Pr ((CH₃)₂CH—), t-Bu ((CH₃)₃C—), Me (CH₃—), n-Bu (CH₃CH₂CH₂CH₂—)), cyclo-alkyl (cyclo-propyl, cyclo-butyl, cyclo-pentyl), olefinic (alkenyl, aryl, allylic), or alkynyl groups (generally without the sp carbon bound directly to the tin), or combinations thereof. In further embodiments, suitable R groups may include hydrocarbyl groups substituted with hetero-atom functional groups including cyano, thio, silyl, ether, keto, ester, or halogenated groups or combinations thereof.

In some embodiments, the coatings can be formed with precursors comprising RSnX₃, (or ore generally RₙSnX₄₋ₙ where n=1, 2, or 3) where X is a hydrolysable group, such as a halide, amide or alkoxide groups, although alkyl tin oxide hydroxide compositions can be directly deposited. Suitable hydrolysable ligands can include, for example, alkynides (R⁰C≡C—), alkoxides (R⁰O—), carboxylates (R⁰COO—), halides, dialkylamides or combinations thereof, where the R⁰ group can be one of the same moieties described above for R. In particular, organotin trialkoxide compositions can be represented by the formula RSn(OR⁰)₃. Also, organotin tridialkylamide compositions can be represented by the formula RSn(NR^{a}R^{b})₃, where the R^{a} and R^{b} groups can be one of the same moieties described above for R. In some embodiments, the organotin compositions can be present in a blended composition such that the blended compositions comprises two or more distinct R groups.

Appropriately selected organotin compounds with hydrolysable ligands have appropriate vapor pressure at reasonable temperature for vapor deposition. Alternatively, the organotin compounds can be dissolved in organic solvents for deposition, such as through spin coating. Water vapor or other oxygen source can be used to hydrolyze in situ the hydrolysable ligands to form the oxo-hydroxo network. The hydrolysis can take place during the coating process, after the coating process or some combination thereof.

For solution based deposition, the thickness of the coating generally can be a function of the precursor solution concentration, viscosity, and process parameters, such as the spin speed. For other coating processes such as vapor deposition, the thickness can generally also be adjusted through the selection of the deposition and coating parameters such as flow rate, cycle time, number of cycles, etc. In some embodiments, it can be desirable to use a thin coating to facilitate formation of small and highly resolved features. In some embodiments, the coating materials can have an average dry thickness prior to development of no more than about 1 micron, in further embodiments no more than about 250 nanometers (nm), in additional embodiments from about 1 nanometers (nm) to about 100 nm, in further embodiments from about 1 nm to about 50 nm, in other embodiments from about 1 nm to about 40 nm and in some embodiments from about 1 nm to about 25 nm. A person of ordinary skill in the art will recognize that additional ranges of thicknesses within the explicit ranges above are contemplated and are within the present disclosure.

Empirical evaluation of the resulting coating material properties generally can be performed to select processing conditions that are effective for the patterning process. While heating may not be needed for successful application of the process, it can be desirable to heat the coated substrate to densify the coating, to improve the processing, to increase the reproducibility of the process, and/or to facilitate vaporization of volatile byproducts. In embodiments in which heat is applied to the coating material after deposition in a post-apply bake (PAB), the coating material can be heated to temperatures from about 45° C. to about 250° C. and in further embodiments from about 55° C. to about 225° C. The heating for solvent removal can generally be performed for at least about 0.1 minute, in further embodiments from about 0.5 minutes to about 30 minutes and in additional embodiments from about 0.75 minutes to about 10 minutes. Final film thickness is determined by baking temperatures and times as well as the initial concentration of the precursor. A person of ordinary skill in the art will recognize that additional ranges of heating temperature and times within the explicit ranges above are contemplated and are within the present disclosure. As a result of the heat treatment, potential hydrolysis, and densification of the coating material, the coating material can exhibit an increase in index of refraction and in absorption of radiation without significant loss of dissolution rate contrast.

Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. Radiation can generally be directed to the substrate material through a mask or a radiation beam can be controllably scanned across the substrate to form a latent image within the resist coating. Following International Standard ISO 21348 (2007) incorporated herein by reference, ultraviolet light extends between wavelengths of greater than or equal 100 nm and less than 400 nm, with extreme ultraviolet (EUV) from greater than or equal 10 nm to less than 121 nm. EUV light has been used for lithography at 13.5 nm, and this light is generated from a Xe or Sn plasma source excited using high energy lasers or discharge pulses. Commercial sources of EUV photons include scanners fabricated by ASML Holding N.V. Netherlands.

Post-Irradiation Processing with Contrast Enhancers and Image Development

Once the latent image is formed by patterned radiation exposure, the structure can be further processed, for example, with an optional post-exposure bake with or without aging, with vapor delivery of contrast enhancers, with image development, and/or with pattern improvement, such as with scum removal. The steps can be organized in any reasonable order, and some of the steps may blend together. If a separate development step is used, such a development can be liquid based or dry, using a thermal or plasma process. Contrast enhancers can generally be small molecule reactants that can selectively diffuse and/or migrate into the low-density (e.g., non-irradiated) regions of the coating to facilitate immediate or subsequent removal of material. Such contrast enhancers can interact with the non-irradiated regions of the coating, such as through complexation, coordination, acid/base chemistry, redox chemistry, or a combination thereof. In any case, it is desirable for the contrast enhancer to possess the necessary reactivity with the organotin matrix in the non-irradiated region such that oxo and hydroxo bonds (e.g., Sn—O—Sn and Sn—OH bonds, or more generally M-O-M and M-OH) can be broken or interrupted, and more volatile or more soluble species can be formed.

Following exposure to radiation and the formation of a latent image, a subsequent post-exposure bake (PEB) is generally performed. In some embodiments, the PEB can be performed in ambient environments, and in additional embodiments the PEB can be performed in the presence of a reactive gas such as H₂O, CO₂, CO, SO₂, H₂S, phosphines, Hz, or others as described in '170 application cited above. In some embodiments, the PEB can be performed at temperatures from about 40° C. to about 350° C., in additional embodiments from about 45° C. to about 300° C., in further embodiments from about 60° C. to about 275° C., and in some embodiments from about 100° C. to about 250° C. The post exposure heating can generally be performed for at least about 0.1 minute, in further embodiments from about 0.2 minutes to about 5 minutes, in additional embodiments from about 0.25 minutes to about 3 minutes, and in other embodiments from about 0.3 minutes to about 2 minutes. A person of ordinary skill in the art will recognize that additional ranges of PEB temperatures and times within the explicit ranges as well as ranges with upper and lower limits exchanged (such as from 0.1 minutes to about 3 minutes) above are contemplated and are within the present disclosure. The PEB can be designed to further densify and/or consolidate the exposed regions without decomposing the un-exposed regions into a metal oxide.

Also, it can be desirable to have a post exposure delay in which the exposed wafer is aged. A post exposure delay can be used as an alternative to a post exposure bake (although neither may be used in some embodiments), or a post exposure delay can be performed prior to a post exposure bake, or a post exposure delay can be performed after a post exposure bake, or a post exposure bake can be performed both after a first post exposure delay and before a second a post exposure bake. The aging step may blur with the post-exposure bake as the temperature may just be allowed to cool to an aging temperature with a continuous time-frame and/or the temperature can be increased to transition from an aging step to the PEB step. If heating is performed during a post exposure delay, the heating temperature is generally lower than the temperature of a post exposure bake, and an appropriate temperature ramp would be used to transition between the different heating domains.

A post exposure delay can be for a time of at least about 10 minutes, in further embodiments at least about 20 minutes, in additional embodiments from about 25 minutes to about 7 days, in some embodiments from about 30 minutes to about 3 days, and in other embodiments from about 40 minutes to about 2 days, and additional ranges explicitly include any and all combinations of the delay end points of these ranges. A post exposure delay (PED) can be performed with a specified atmosphere over the wafer, such as air, air with a modified gas content, N₂, argon or other inert gas, or vacuum, as described herein. A post-exposure delay can be performed generally at a pressure from about 200 Torr to about 1200 Torr, and may be performed at roughly atmospheric pressure. Process pressures are described further below. A post exposure delay can be performed at ambient temperature or at an elevated temperature, which may accelerate process times to allow for a shorter delay. The temperature during a post exposure delay or a selected portion of the post exposure delay can be from about 30° C. to about 150° C., in additional embodiments from about 40° C. to about 130° C., in further embodiments from about 50° C. to about 120° C., and in some embodiments from about 55° C. to about 95° C., as well as explicitly including additional ranges based on these temperature end points such as from 30° C. to 95° C. A person of ordinary skill in the art will recognize that additional ranges of time and temperature within the explicit ranges above are contemplated and are within the present disclosure. Higher temperatures generally are not maintained for long periods of time. But the various process parameters can be optimized based on the teachings herein to obtain desirable improvements in the patterning.

Exposure to radiation for the organometallic resist compositions generally involves bond cleavage. In resist compositions of particular interest, bond cleavage generally involves breaking of carbon—metal bonds. The breaking of carbon metal bonds can leave reactive species, such as radicals and/or metal atoms with ability to form another ligand—metal bond. The organic species generally form gaseous by-products that exit the material, and the metal oxide hydroxide condenses toward a more metal oxide-like structure and/or forms a network of tightly bonded species to densify such that the patterned structure has a high etch contrast between the irradiated and non-irradiated regions. For example, the densified irradiated coating becomes more insoluble in organic solvents used to solubilize the original organometallic composition.

Post exposure processing is generally directed to facilitating and enhancing the network formation and densification of the exposed coating. Heating generally can accelerate solid state reorganizations of lattice structures, which generally is part of the densification process, and heating can also facilitate certain reactions. Excessive heating though can have effects on the non-irradiated portions of the coating that could decrease development contrast, so heating should be controlled appropriately. Further aging through a post exposure delay prior to development of the latent image can provide further time for the densification process to occur. During post coating processing, the atmosphere surrounding the coated wafer can significantly influence the effects of the processing. The atmosphere can be characterized by composition and pressure.

A densification process involves a small volume change, so an increase in pressure would tend to thermodynamically favor densification. The converse generally is also true, such that lowering the pressure would tend to thermodynamically disfavor densification. Results presented in the '170 application in which a vacuum applied during a post exposure delay, were shown to result in a decrease in etch contrast. Similarly, the chemical nature of the atmosphere can alter the effects of port exposure processing. Suitable gaseous atmospheres can include, for example, air, air plus additional gases, nitrogen, argon and other inert gases, and reactive gases. Some heat can be applied during a post exposure delay separate from or along with a separate post exposure bake, which may be a higher temperature than heating during the post exposure delay, such that the two process regimes are distinguished.

Regardless of the chemical composition of the atmosphere over the wafer at various process points, the pressure can be correspondingly adjusted. The atmospheric pressure at the process facility can serve as a baseline. Since most facilities are above sea level, the actual average atmospheric pressure is less than a standard atmospheric pressure, and weather induced further temporal changes. Also, ventilation systems can be set to maintain a slight negative pressure relative to the outside pressure to control relative flow of gases into or out from the facility. Within a process chamber, a slight overpressure can be maintained to turn over the gases in the chamber. A person of ordinary skill in the art will recognizes these pressure issues, and from a practical perspective, pressures from about 600 Torr to about 800 Torr can be considered atmospheric pressure, and in some embodiments pressures from 800 Torr to 1200 Torr can be of interest with respect to maintaining a positive pressure flow of an atmosphere in contact with a wafer. Other pressure ranges can be useful for processing. Another range of potential interest includes pressure of at least about 200 Torr, and for the processing of wafers vacuum or low pressure can be considered any pressure of no more than about 1 Torr. A person of ordinary skill in the art will recognize that additional pressure ranges within the explicit ranges above are contemplated and are within the present disclosure.

Reaction of the contrast enhancer with the organotin matrix can result in the formation of more easily removable, perhaps more volatile, species that can then immediately or subsequently removed from the substrate. Reactions mediated by the contrast enhancer can generally include addition reactions, substitution reactions, and/or acid/base neutralization reactions. In some embodiments, reaction with the oxo and hydroxo bonds can generally be achieved by replacement of network-forming —O— and/or —OH ligands with ligands having much less propensity for network formation. In some embodiments, reactions that induce ligand replacement in the organotin matrix can comprise an acid/base neutralization reaction, e.g.:

RSnOH+HX→RSnX+H₂O

RSnO+XOH→RSnX+H₂O

The propensity for a contrast enhancer to react with and replace an —O— or —OH ligand can generally depend on its pKa. In some embodiments, the contrast enhancer can be protic and can drive protonation of the —O— and/or —OH ligands to disrupt the organotin oxo-hydroxo network and to result in lower molecular weight species that are readily removed in development. In other embodiments, the contrast enhancer can be aprotic.

In some embodiments, the contrast enhancer can comprise compounds capable of undergoing substitution reactions wherein ligand replacement is achieved in the organotin matrix, e.g.:

RSnOH+AX→RSnX+AOH

In some embodiments, the contrast enhancer can comprise nucleophilic compounds capable of undergoing addition reactions wherein the contrast enhancer can complex, coordinate, or similarly interact with the organotin matrix to produce a new composition, e.g.:

RSnOH+X→RSnXOH

For the general reactions above, introduction of the contrast enhancer in a continuous or pulsed flow in a thermal development process can be beneficial to drive the reaction equilibria forwards by continuously removing products, e.g. H₂O, while continuously supplying reactant(s). Similarly, if the tin product is similarly vaporized in a one-step process, this further drives the equilibria forward while achieving the development goal, whether or not development is driven to completion this way or if a further separate development is performed. It should also be understood that the above reactions are intended to be illustrative and not limiting.

The use of the contrast enhancer can be used in one or more roles in the process flow. For example, it can be used post irradiation and after an optional post-exposure bake to modify differentially the pattern. At this stage of processing, the contrast enhancer may result in partial or essentially complete removal of the non-irradiated organometallic composition. This processing can span a continuous range over these boundaries from no significant tin removal to essentially complete tin removal from the non-irradiated regions. Further processing can be selected accordingly, as described below. In additional or alternative embodiments, contrast enhancers can be delivered following a distinct development step, which can be a liquid development step or a dry development step, such as a vapor development using a distinct contrast enhancer agent (thermal dry development) or a plasma etch as a dry development, as well as a dry development step using a contrast enhancer as described herein. The use of a post development step of contrast enhancer can provide for pattern improvement, such as descumming, microbridge removal, and the like. In any case, the tin reaction products can be removed in-situ, i.e., during the course of the reaction, to facilitate pattern development.

Proper selection of contrast enhancer can also depend on the relative density differences between the irradiated and non-irradiated material. For negative-tone development, it can be desirable for the contrast enhancer to selectively diffuse into the non-irradiated regions in order to facilitate removal the material in that region. It can therefore be desirable for the contrast enhancer to possess balance between steric bulk and acidity. In other words, it can be desirable for a contrast enhancer to bind and diffuse selectively in the non-irradiated regions so that it only reacts substantially in that region. Depending on the composition and processing of the organotin coating, a range of material densities can be present in the coating. For example, for organotin compositions with bulkier R groups as defined above, radiation-induced decomposition may lead to a larger volume loss in comparison to compositions having smaller R groups.

The density of the organotin photoresist coating can generally depend on both chemical composition and processing of the related coating. In general, prior to irradiation, organotin compositions having larger or bulkier R groups, such as tert-butyl (CH₃)₃C—, have a smaller tin number density than compositions having smaller R groups, such as methyl CH₃. Density can be roughly correlated with the number of Sn—O—Sn and/or Sn—OH bonds within a given volume, and bulkier R groups generally increase the distance between such bonds. After irradiation with an appropriate radiation source, such as EUV photons, the irradiated material is able to condense to a greater extent than the non-irradiated material due to the depletion of condensation inhibiting R groups in the irradiated region.

Processing of the coating can also affect its density, particularly processes or steps that increase the concentration of Sn—O—Sn and/or Sn—OH bonds. For example, baking the substrate at higher temperatures generally densifies and condenses the coating and therefore increases the concentration of Sn—O—Sn and/or Sn—OH bonds. Sn—O—Sn and Sn—OH bonds can be terminal or bridging, for example bridging two or more Sn atoms through O and/or OH linkages. The density of the material generally increases with the concentration of bridging O and OH linkages and thereby making it more difficult for contrast enhancers and other reactants to diffuse into the matrix. As discussed above, the density of the irradiated material is generally higher than the non-irradiated material.

Hydrophobicity and/or polarity of the organotin coating can also affect proper selection of contrast enhancer. Coatings having more carbon, e.g., compositions with R groups having more C atoms, are generally less polar than coatings with less carbon. Similarly, after exposure to radiation, the non-irradiated regions generally comprise substantially intact Sn—C bonds, i.e., comprising intact R groups, whereas the irradiated regions generally comprise significantly less Sn—C bonds, i.e., significantly less C content. In this way, polarity of the coating can be specifically controlled by processing and chemical composition of the organotin coating. Less polar reactants generally would be more penetrating into less polar non-irradiated portions of the coating.

Suitable contrast enhancers, for example, can comprise amines (e.g., RNH₂, R₂NH, R₃N), silicon and silyl halides (e.g., SiX₄, RₙSiX₄₋ₙ), alcohols (e.g., ROH) and thiols (e.g., RSH), diols (e.g., ROHR′OH), carboxylic acids (e.g., RCOOH) and amides derivatives (e.g., RCONH₂), sulfonic acids (e.g., RSO₂OH), and combinations and mixtures thereof, where R and R′ are independently linear, branched, or cyclic hydrocarbon groups having 1 to 10 carbons. For vapor delivery, the contrast enhancer should have sufficient vapor pressure at the process temperatures. In some embodiments, the substrate can be exposed to one or more of these agents simultaneously or separately.

In some embodiments, contrast enhancers that drive addition reactions can be used, for example, amines. Specifically, suitable amines can comprise ammonia NH₃ and/or alkylamines and their isomers with alkyl chains having 1 to 4 carbons, such as trimethylamine, triethylamine, tripropylamine, tributylamine, dimethylamine, diethylamine, dipropylamine, diisopropylamine dibutylamine, diisobutylamine, methylamine, ethylamine, propylamine, butylamine, pyridine, pyrrolidine, and the like, and mixtures thereof. Further examples of suitable amines can comprise silyl derivatives, for example, trimethylsilyl amines such as trimethylsilyl tris(dimethylamine) (CH₃)₃Si(NMe₂)₃ and trimethylsilyl tris(diethylamine) (CH₃)₃Si(NEt₂)₃. In some embodiments, mixtures of silyl amides and alkylamines can be used. As described further below, a contrast enhancer can be delivered along with an inert gas

In some embodiments, contrast enhancers that drive substitution reactions can be used, for example, a group 14 halide such as silicon and/or silyl halide, a germanium halide, and/or a tin halide. Suitable group 14 halides can comprise, for example, compositions represented by the formula RₙMX₄₋ₙ, wherein M=Si, Ge, or Sn, R═CH₃ or CH₃CH₂, n=0 to 3, and X═Cl or Br. Suitable compositions where M=Si can be, for example, trimethylsilyl chloride (CH₃)₃SiCl, trimethylsilyl bromide (CH₃)₃SiBr, dimethylsilyl chloride (CH₃)₂SiCl₂, dimethylsilyl bromide (CH₃)₂SiBr₂, monomethylsilyl chloride (CH₃)SiCl₃, monomethylsilyl bromide (CH₃)SiBr₃, tetrachlorosilane SiCl₄, tetrabromosilane SiBr₄, and combinations thereof. The analogous Ge and Sn halide compositions can also be used. Steric bulk of group 14 halides can generally be correlated with degree of alkylation of the M atom, for example, (CH₃)₃SiCl is generally more bulky than (CH₃)SiCl₃. Furthermore, acidity of the group 14 halide is generally indirectly correlated with the degree of alkylation of the M atom, for example, (CH₃)₃SiCl is generally less acidic than (CH₃)SiCl₃. Proper selection of group 14 halide can be driven by density and/or hydrophobicity differences between the irradiated and non-irradiated regions of the photoresist coating, as well as by the pKa of the group 14 halide.

In some embodiments, an alcohol can be used to drive addition reactions, substitution reactions, or a combination thereof. Suitable alcohols can comprise R—OH wherein R is a linear, branched, or cyclic alkyl group having 1 to 10 carbons, for example, but not limited to, methanol, ethanol, n-propanol, iso-propanol, 1-butanol, iso-butanol, tert-butanol, 1-pentanol, 4-methyl-2-pentanol, cyclopentanol, 1-hexanol, cyclohexanol, phenol, and the like, and combinations thereof.

In some embodiments, the alkyl group can comprise hydrogen atoms substituted with halogens (e.g., F, Cl, I, Br), for example nonafluoro-tert-butyl alcohol ((CF₃)₃COH), pentafluorophenol (C6F5OH), and the like. Proper selection of alcohol contrast enhancer can be driven by hydrophobicity and/or steric hindrance of the —OH group, such that diffusion of the agent into the non-irradiated regions of the coating is optimal. For example, primary alcohols are generally less sterically hindered than secondary alcohols, which are in turn generally less sterically hindered than tertiary alcohols. In some embodiments, thiol derivatives of alcohols can be used, such as methanethiol, ethanethiol, propanethiol, isopropanethiol, butyrothiol, isobutyrothiol, tert-butylthiol, and the like, and combinations thereof. Alcohols can be halogenated, such as fluorinated. In some embodiments, a mixture of an alcohol and a thiol can be used. In some embodiments, selection of the alcohol can be based in part on the volatility of the tin containing reaction product.

In some embodiments, a diol can be used. Suitable diols can comprise compositions having 1 to 10 carbon atoms and their isomers, and their cyclic and ether analogues, for example, but not limited to, methylene glycol, ethylene glycol, diethylene glycol, propylene glycol, dipropylene glycol, cyclohexanediol, mixtures thereof, and the like.

In some embodiments, a carboxylic acid can be used. Suitable carboxylic acids can comprise compounds with alkyl chains having 1 to 10 carbon atoms and their isomers, such as formic acid HCOOH, acetic acid CH₃COOH, propionic acid CH₃CH₂COOH, butyric acid CH₃(CH₂)₂COOH, isobutyric acid (CH₃)₂CHOOH, benzoic acid (C₆H₅)COOH and the like, and combinations thereof. In some embodiments, the alkyl chain can comprise hydrogen atoms substituted with halogens (e.g., F, Cl, I, Br), for example trifluoroacetic acetic acid (CF₃COOH), trichloroacetic acid (CCl₃COOH), and the like. In some embodiments, amide derivatives of carboxylic acids can be used, and such amides can comprise, for example, formamide, N-methylformamide, acetamide, urea, propanamide, butyramide, isobutyramide, and the like, and combinations thereof. In some embodiments, mixtures of carboxylic acids and amides can be used.

In some embodiments, a sulfonic acid can be used. Suitable sulfonic acids can comprise compositions represented by the general formula RSO₂OH wherein R is a linear, branched, or cyclic alkyl chain having from 1 to 10 carbon atoms, for example, methanesulfonic acid, ethanesulfonic acid, propanesulfonic acid, benzenesulfonic acid, p-toluenesulfonic acid (C₇H₇SO₂OH), and the like, and combinations thereof. In some embodiments, R can comprise alkyl chains having hydrogen atoms substituted with halogens (e.g., F, Cl, I, Br), for example triflic acid (CF₃SO₂OH). In other embodiments, R can comprise functional groups such as amines (—NH₂), thiols (—SH), and alcohols (—OH).

In some embodiments, the contrast enhancer composition may further comprise water. For some contrast enhancers, for example, carboxylic acids, water can be difficult to fully eliminate from the source, and it may further facilitate delivery of the contrast enhancer to the surface of the substrate. It can be also desirable to include a hydrogen halide (HF, HCl, HBr, HI, or mixture thereof) gas in addition to or as an alternative to water as a reactant aid for delivery with a contrast enhancer as described herein. Water and hydrogen halides as reaction facilitators can be delivered over the same partial pressure ranges as the contrast enhancers. Similarly, it can be desirable to used mixtures of contrast enhancing agents that can be delivered simultaneously, sequentially or some combination thereof.

One of ordinary skill in the art will realize that a desirable selection of contrast enhancer can depend on specific organotin compositions and processing variables, and routine experimentation can inform proper selection based on the teachings herein. As discussed above, pKa of a given contrast enhancer can influence the reaction rate during development. While not wanting to be limited by theory, it is generally expected that contrast enhancers having a low pKa, such as carboxylic and sulfonic acids, or a high pKa relative to the organotin matrix can drive acid/base neutralization reactions to facilitate removal of the neutralized species. Appropriate choice of contrast enhancer can therefore be informed by desired pKa along with other factors discussed herein.

Steric bulk is also a factor with respect to diffusion of the contrast enhancer to the reaction surface and into the organotin matrix. For example, and while not wanting to be limited by theory, it is believed that compositions comprising trimethylsilyl (TMS) groups can be useful in tuning particular contrast enhancer compositions due to the size of the TMS group and its general similar behavior to an H substituent, and it therefore presents a unique opportunity to appropriately tune the composition of contrast enhancer for development of given organotin composition. In other examples, substitution of a contrast enhancer's R group with a bulkier group can decrease the reaction rate in the irradiated region due to the lower ability to diffuse into a dense organotin oxo-hydroxo matrix. In some embodiments, a plurality of contrast enhancers can be used simultaneously or in series. In some embodiments, the contrast enhancer can be delivered in the presence of or with an inert gas, such as N₂, He, Ne, Ar, Kr, and/or Xe, which generally involves a pulsed or continuous flow through the system.

Introduction of contrast enhancing agents, which can function as volatilizing gases, to react with the irradiated coating can generally be performed after exposure to radiation. In some embodiments, it can be beneficial to perform a post-exposure bake (PEB) on the irradiated substrate to heat the coating and to further condense the irradiated regions, thereby increasing the chemical (e.g., hydrophobicity) and/or physical (e.g., density) contrast between the irradiated and non-irradiated regions. The application of a post-exposure bake is described further above. The specific conditions of the post exposure bake can be adjusted to be consistent with the selection of a contrast enhancing agent to achieve desired performance from the contrast enhancing agent. After exposure to radiation, the irradiated regions generally have less carbon content than the non-irradiated regions, and therefore can generally be driven to higher densities relative to the non-irradiated regions.

Whether or not a post-exposure bake is performed, it can be desirable to apply heat simultaneously with development and/or with exposure to the contrast enhancer. The heat can by useful to volatilize the reaction products to allow their removal from the process chamber as well as facilitating the reaction with the contrast enhancing agent. The wafer/substrate, the gases and/or the chamber itself can be heated or cooled to provide a desired temperature for the processing. The temperature can be from about −45° C. to about 350° C., in further embodiments from about −10° C. to about 300° C., and in additional embodiments from about 0° C. to about 250° C. The reaction time can be at least about 0.1 minutes, in further embodiments from about 10 seconds to about 5 minutes, and in additional embodiments from about 20 second to about 3 minutes. In some embodiments, the chamber pressure can be from about 100 Torr to about 1200 Torr and in further embodiments from about 200 Torr to about atmospheric pressure (roughly 760 Torr), although as noted below, the gas in the chamber is generally in a flow, and the flow rate is also significant. To maintain these pressures in view of lower partial pressures of reactant gas, an inert diluting gas can be delivered with the contrast enhancer. In alternative embodiments, an inert gas may not be used, such that the chamber pressure is approximately equal to the partial pressure of the contrast enhancer, as specified below. A person or ordinary skill in the art will recognize that additional ranges of reaction/heating time, pressure and temperature within the explicit ranges above are contemplated and are within the present disclosure.

The contrast enhancer can be introduced to the process chamber containing the substrate by flowing the vaporized contrast enhancer into the chamber at a desired flow rate and/or at a constant pressure. If more than one contrast enhancer and/or inert gas are used in the process, the partial pressures and/or flow rates of each individual contrast enhancer or inert gas can be controlled. In some embodiments, the partial pressure of each contrast enhancer and/or inert gas in the chamber can be from between about 1 millitorr (mTorr) and about 10 Torr, in some embodiments from about 10 mTorr to about 8 Torr in other embodiments, from about 50 mTorr to about 7 Torr in other embodiments, and from about 100 mTorr to about 5 Torr in further embodiments. Pressures may be controlled with a particular pumping rate by varying the flow rates of each individual reactive gas into the process chamber, for example, from about 0.5 sccm to about 1000 sccm, in some embodiments, from about 1 sccm to about 500 sccm in other embodiments, and from about 2 sccm to about 200 sccm in further embodiments. Whether higher or lower chamber pressures are used, the chamber pressure can be changed during the course of processing as desired. Inert gases, if used, can be delivered at higher rates and can be used to maintain higher chamber pressures without changing a selected flow rate for a reactive gas. Inert gas flow rates can be from about 0.5 standard liters per minute (SLM) to about 30 SLM, in further embodiments from about 1 SLM to about 20 SLM and in additional embodiments form about 3 SLM to about 15 SLM. It should generally be understood by one of ordinary skill in the art that desirable gas flow rates can depend on the size of the chamber used to perform the processing. In general, lower gas flow rates can be used for smaller chambers and higher flow rates can be used for larger chambers. For example, for a process comprising chamber having a size of about 1 L and a gas flow rate of 1-100 sccm, it can be expected that a larger 50 L chamber would require a correspondingly ˜50× higher flow rate of 50-5000 sccm. One of ordinary skill in the art will understand that additional ranges of pressures and flow rates within the above ranges are contemplated and within the scope of the disclosure.

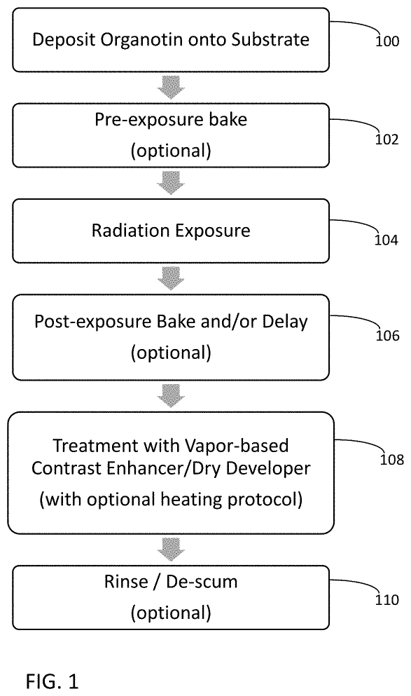

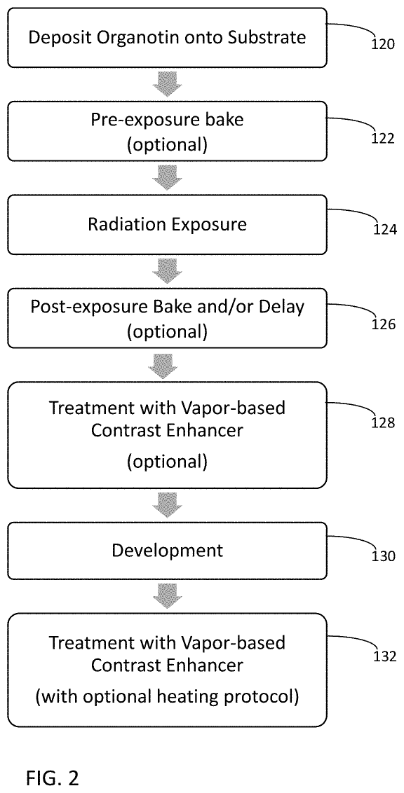

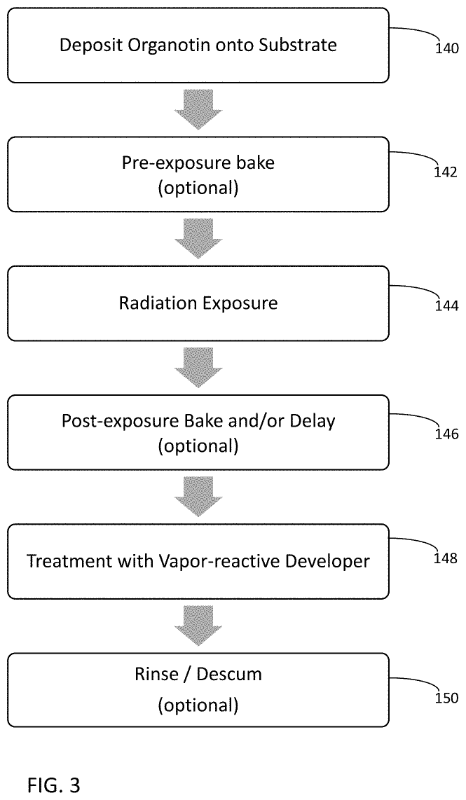

The process flow for the use of contrast enhancers is presented conveniently in three figures to show more specifics embodiments relating to some presently desirable implementations. FIG. 1 shows a flow chart of latent image process of a patterned organotin coating in which the contrast enhancer is used prior to treatment with a dry developer, although alternative embodiments can involve liquid developer. FIG. 2 shows a flow chart of latent image processing of a patterned organotin coating in which the contrast enhancer is used after a development step for pattern improvement. FIG. 3 shows a flow chart of latent image processing of a patterned organotin coating in which the contrast enhancer is employed as a vapor reactive developer.

In the flow chart of FIG. 1, organotin composition is deposited onto a substrate 100. Deposition may use a solution-based approach, such as spin-coating, or a vapor-based approach, such as physical vapor deposition (PVD), chemical vapor deposition (CVD), atomic layer deposition (ALD), or modifications thereof. After optional pre-exposure bake 102, the coated substrate is exposed to radiation 104, such as EUV radiation, to form a coating with a latent image. After optional post-exposure bake (PEB) and/or delay 106, the patterned coated substrate is subjected to treatment with vapor-based contrast enhancer/dry developer 108 within a suitable chamber. An optional heating protocol for use with the contrast enhancer may include controlling the temperature of the contrast enhancer, controlling the temperature of the substrate, and/or performing a post-treatment bake. After contact with the contrast enhancer for a selected period of time and at a selected flow rate/chamber pressure, the coated substrate is then contacted with a vapor-based dry developer that is distinct from the contrast enhancer. An optional heating protocol may include controlling the temperature of the dry developer, controlling the temperature of the substrate, or performing a post-development bake. Treatment with vapor-based contrast enhancer 108 may be repeated.

Partial development of the image, in other words non-irradiated material removal, may be simultaneous with the treatment with the contrast enhancer. Reaction products, including volatile species, may be removed from the chamber during the treatment step. In some embodiments, volatile species are removed from the surface of the coating and/or from the chamber using the flow of the reactive gas. In some embodiments, pulses of purge gas may be used. The removal of volatile species may be continuous during the treatment with the contrast enhancer and/or the dry developer or a discrete period during the treatment. In other embodiments, the reaction products are removed with a rinse liquid, such as after the treatment with the contrast enhancer and prior to treatment with the dry developer, although alternative embodiments can comprise use of the liquid developer. The rinse liquid may be delivered at a selected temperature, such as room temperature. If a distinct development step is used, dry development can be performed using previously identified reactant gases for thermal development or using a plasma. The contrast enhancers described herein can be effective for facilitating the development process, acting as a dry development reactant and/or as an effective agent for pattern improvement following separate development as an alternative to a liquid rinse.

After development, the substrate is then subjected to optional rinse/de-scum 110 to provide an improved patterned substrate, for example, by descumming, microbridge removal, or other feature enhancement. Rinse/de-scum 110 may remove a portion of the developed coating to control pattern dimensions. In some embodiments rinse/de-scum 110 may remove products of the reaction with the contrast enhancer. Rinse/de-scum 100 may involve rinsing with a liquid that is a solvent for the developed coating and/or de-scumming with a vapor-based contrast enhancer, optionally with incorporation of drying or baking steps. The conditions for use of a vapor based contrast enhancer for pattern improvement/de-scumming can be within the same ranges described above for pre-development contrast enhancement, and adjustment can be made to obtain desired results based on the teachings herein. Use of a rinse solution for pattern improvement is described further in published U.S. patent application 2020/0124970 to Kocsis et al. (hereinafter the '970 application), entitled “Patterned Organometallic Photoresists and Methods of Patterning,” incorporated herein by reference.

Referring to the flow chart of FIG. 2, organotin composition is deposited onto a substrate 120. Deposition may use a solution-based approach, such as spin-coating, or a vapor-based approach, such as physical vapor deposition (PVD), chemical vapor deposition (CVD), atomic layer deposition (ALD), or modifications thereof. After optional pre-exposure bake 122, the coated substrate is exposed to radiation 124, such as EUV radiation, to form a coating with a latent image. After optional post-exposure bake (PEB) and/or delay 126 and optional treatment with vapor-based contrast enhancer 128, the patterned coated substrate is subjected to development 130. Development 130 may be a liquid-based or a vapor-based process. Vapor based development is exemplified below. In general, processing with a contrast enhancer can involve some volatilization of non-irradiated organotin patterning composition along with chemical modification. Any degree of material removal can be beneficial. To the extent that the contrast enhancer results in all or essentially of the removal of the non-irradiated organotin composition, the contrast enhancer can be considered a dry developing agent. Optional wet development or alternative dry development processes are described further below.

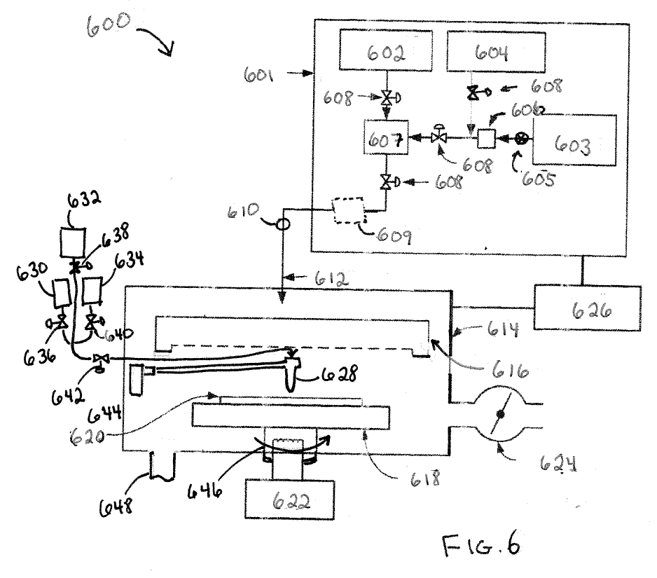

After development 130, the patterned coated substrate can be subjected to treatment with vapor-based contrast enhancer 132, within a suitable chamber, to provide an improved patterned substrate. The treatment time, the flow rate of the contrast enhancer vapor, and/or the chamber pressure may be adjusted, and appropriate parameter ranges are discussed in detail above. An optional heating protocol may include controlling the temperature of the contrast enhancer, controlling the temperature of the substrate, performing a post-development drying and/or baking step, and/or performing a post-treatment bake. As a further option, a rinse/de-scumming step may be performed after the treatment with vapor-based contrast enhancer 132. Reaction products, including volatile species, may be removed from the chamber during treatment with vapor-based contrast enhancer 132. In some embodiments, volatile species are removed from the surface of the coating and/or from the chamber during the vapor treatment process or optionally using a purge gas. In some embodiments, pulses of purge gas may be used. In other embodiments, reaction products are removed with a rinse liquid after the treatment with vapor-based contrast enhancer 132, and the rinse liquid may be alternatively considered a liquid developer. The rinse liquid may be delivered at a selected temperature, such as room temperature. A process according to FIG. 2, may be performed by sequentially using suitable chambers for the depositing organotin onto substrate 120, optional treatment with vapor-based contrast enhancer 128, development 130, and treatment with vapor-based contrast enhancer 132. Alternatively, a process according to FIG. 2, may be performed in a multi-functional chamber process system designed to accommodate both liquid and vapor-based processes, such as described below with respect to an example in FIG. 6.

Referring to the flow chart of FIG. 3, in the outlined procedure, organotin composition is deposited onto a substrate 140. Deposition may use a solution-based approach, such as spin-coating, or a vapor-based approach, such as physical vapor deposition (PVD), chemical vapor deposition (CVD), atomic layer deposition (ALD), or modifications thereof. After optional pre-exposure bake 142, the coated substrate is exposed to radiation 144, such as EUV radiation, to form a coating with a latent image. After optional post-exposure bake (PEB) and/or delay 146, the patterned coated substrate is subjected to treatment treated with vapor-reactive developer 148, within a suitable chamber, to provide a physically patterned coating on the substrate. The temperature of the vapor-reactive developer, the temperature of the substrate, and the outflow of volatile species from the chamber can be controlled during treatment with vapor-reactive developer 148. Reaction products, including volatile species, may be removed from the chamber during the treatment step. In some embodiments, volatile species are removed from the surface of the coating and/or from the chamber using the reactant gas flow or separately using a purge gas. In some embodiments, pulses of purge gas may be used. The removal of volatile species may be continuous during treatment 148 or at discrete periods during treatment 148. In other embodiments, the reaction products and/or residual material can be removed after treatment 148 using a rinse liquid. The rinse liquid may be delivered 150 at a selected temperature, such as room temperature. During optional contact with a rinse liquid, the substrate is subjected to rinse/descum 150 to provide an improved patterned substrate, for example, by descumming, microbridge removal, or other feature enhancement. Rinse/descum 150 may remove a portion of the developed coating to control pattern dimensions. In some embodiments rinse/descum 150 may remove products of the reaction with the vapor-reactive developer resulting from treatment 148. Rinse/de-scum 150 may involve rinsing with a liquid that is a solvent for the developed coating and/or de-scumming with a vapor-based contrast enhancer, optionally with incorporation of drying or baking steps. In alternative or additional embodiments, contrast enhancer can be delivered after development 148 using a different contrast enhancing composition to perform the process of pattern improvement.

It can be desirable to control the temperature of the development process to help tune the etch selectively between, for example, the irradiated and non-irradiated regions, or between any regions of the resist and other layers that may be at least partially exposed to the contrast enhancer and/or plasma ions and/or radicals. In some embodiments, various heating and/or cooling elements and associated controllers may be present within or around the chamber. In some embodiments, the substrate mount may comprise a heating element capable of heating the wafer within the chamber. In other embodiments, the substrate mount may comprise a cooling element capable of cooling the wafer within the chamber. In other embodiments, the substrate mount can include an element capable of heating or cooling the wafer.

In some embodiments of the processing, a number of inlets and outlets can be attached to the chamber to afford delivery of desired gases into the chamber and for removal of species from the chamber via vacuum or gas flow. A mount for a substrate comprising the photoresist desired to be developed can be present within the chamber, or in close proximity to the chamber such that the contrast enhancers and/or related plasma-generated ions and/or radicals can reach the photoresist on the substrate surface.

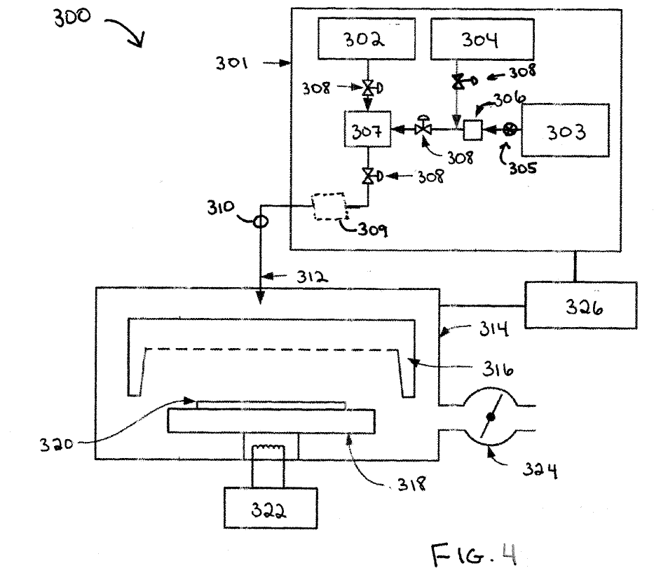

A schematic layout of a suitable process system 300 for a vapor based treatment is presented in FIG. 4. Process system 300 has vapor delivery system 301 and process chamber 314. In some embodiments, vapor delivery system 301 has process gas 302. In some embodiments, vapor delivery system 301 has a reservoir of process liquid 303 for vapor delivery. Process gas supply 302 and/or process liquid reservoir 303 comprise contrast enhancers as described above. In some embodiments, vapor delivery system 301 has a supply of inert gas 304. Process liquid 303 can be delivered via liquid flow controller 305 to vaporization unit 306. Mixing unit 307 receives a controlled flow of process gas 302, vaporized process liquid, and/or inert gas 304, each of which is controlled via one or more inlet valve 308. In some embodiments, vapor delivery system 301 has plasma unit 309. Temperature controller 310 is provided to control the temperature of process vapor 312 entering process chamber 314.

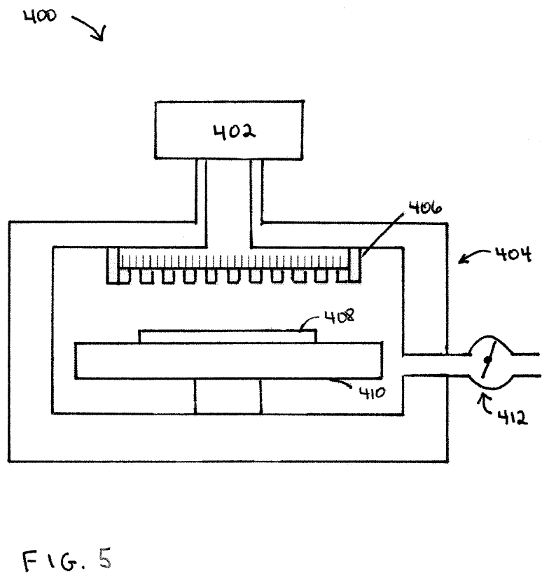

Process chamber 314 has vapor distribution unit 316. Vapor distribution unit 316 may have a selection from various suitable shapes and designs. In some embodiments, vapor distribution unit 316 has a showerhead shape with a multiple port design, one embodiment of which is shown in FIG. 5. Process chamber 314 has support 318. Substrate 320 is located beneath vapor distribution unit 316 and rests on support 318. In some embodiments, support 318 may be temperature controlled via heating/cooling unit 322. Support 318 may be connected to a motor to spin support 318 for substrate processing. Support 318 may be manually or remotely raised or lowered to adjust the distance between the substrate and the vapor distribution unit. Pressure valve 324 provides for control of the pressure and the concentration of volatile reaction products in process chamber 314. Pressure valve 324 may be connected to a pump, such as a vacuum pump. In some embodiments, controller 326 is provided to remotely control the elements of process system 300.

FIG. 5 shows one embodiment of vapor distribution unit 306 as part of a simplified depiction of process system 300. Process system 400 is shown having vapor delivery system 402 and process chamber 404 having pressure valve 412. Within process chamber 404 is showerhead vapor distribution unit 406, substrate 408, and support 410. Showerhead vapor distribution unit 406 is shown with an optional gated nano-channel grid to provide more uniform vapor contact over the substrate surface.

FIG. 6 shows a schematic layout of a suitable multi-functional chamber process system 600. Process system 600 has vapor delivery system 601 and process chamber 614. In some embodiments, vapor delivery system 601 has a reservoir of process gas 602. In some embodiments, vapor delivery system 601 has a reservoir of process liquid 603. Reservoir of process gas 602 and/or reservoir of process liquid 603 comprise contrast enhancers as described above. In some embodiments, vapor delivery system 601 has a reservoir of inert gas 604. Process liquid 603 can be delivered via liquid flow controller 605 to vaporization unit 606. Mixing unit 607 receives a controlled flow of process gas 602, vaporized process liquid, and/or inert gas 604, each of which is controlled via one or more inlet valve 608. In some embodiments, vapor delivery system 601 has plasma unit 609. Temperature controller 610 is provided to control the temperature of process vapor 612 entering process chamber 614.

Process chamber 614 has vapor distribution unit 616. Vapor distribution unit may have a selection from various suitable shapes and designs. In some embodiments, vapor distribution unit 616 has a showerhead shape with a multiple port design, one embodiment of which is shown in FIG. 6. Process chamber 614 has support 618. Substrate 620 is located beneath vapor distribution unit 616 and rests on support 618. In some embodiments, support 618 may be temperature controlled via heating/cooling unit 622. Fluid delivery nozzle 628 receives a controlled flow from process liquid reservoir 630, process liquid reservoir 632, or process liquid reservoir 634, controlled via inlet valves 636, 638, and 640 respectively, and inlet valve 642. In some embodiments, process liquid reservoir 630 stores a organotin precursor solution. In some embodiments, process liquid reservoir 632 stores a developer liquid. In some embodiments, process liquid reservoir 634 stores a rinse liquid. Retractable arm 644 is provided to support fluid delivery nozzle 628 and allow adjustment of the location of fluid delivery nozzle 628, which may also provide for moving delivery nozzle 628 out of the way of vapor delivery. Support 618 is connected to motor 646 to spin support 618 for substrate processing, such as deposition of a film onto a substrate via spin-coating, liquid-based development, and/or rinsing/de-scumming. Drain 648 is provided for removal of processing liquids. Support 618 may be manually or remotely raised or lowered to adjust the distance between the substrate and the vapor distribution unit. Pressure valve 624 provides for control of the pressure and the concentration of volatile reaction products in process chamber 614. Pressure valve 624 may be connected to a vacuum pump. In some embodiments, controller 626 is provided to remotely control the elements of process system 600.

More specifically, the development process can generally comprise introducing and contacting the treated coating on the substrate in a thermal and/or plasma process. In some embodiments, the thermal process may comprise controlling the temperature of the contrast enhancer before contacting it with the coated substrate. In additional or alternative embodiments, the thermal process may comprise controlling the temperature of the substrate during contact with the contrast enhancer. Such thermal processes can generally include cooling or heating. In some embodiments with highly reactive contrast enhancers (i.e., contrast enhancers having significantly high pKa or low pKa), it may be beneficial to cool the substrate during its exposure to the contrast enhancer in order to better control the removal rates and improve the subsequent pattern fidelity. In embodiments in which cooling in used, the thermal process can be from around −80° C. to about 0° C., in other embodiments from about −60° C. to about −20° C., and from about −50° C. to about −30° C. in further embodiments. For some cooling embodiments, liquid nitrogen can be a particularly useful coolant. In other embodiments, the thermal process can comprise heating the substrate. In some embodiments, temperature ranges suitable for conducting the thermal process can be from about 20° C. to about 400° C., in other embodiments from about 40° C. to 300° C., and in further embodiments from about 50° C. to 200° C. The duration of the thermal process can be from about 0.1 minutes to about 10 minutes in some embodiments, from about 0.2 minutes to about 5 minutes in further embodiments, and from about 0.3 minutes to about 2 minutes in still further embodiments. One of ordinary skill in the art will understand that additional ranges of temperatures and durations within the above ranges are conceived and within the scope of the disclosure.

As discussed in the context of the process flows of FIGS. 1-3, in some embodiments, the use of the contrast enhancers can be used around and in support of a separate development step. With respect to separate development steps, a liquid development step or a dry development step can be used. Dry development steps can be based on gases that develop the non-irradiated material in a thermal process and/or through the use of plasma. As described above, the development step can be used in selected process positions relative to the use of the contrast enhancer.

In some embodiments, it may be desirable to contact the irradiated substrate with a plasma to perform the development, as a separate step from treatment with a gas/vapor contrast enhancer. In a plasma dry development process, the photoresist is exposed to suitable chemical species including ions and/or radicals of one or more gases. The dry development process may occur in a plasma-generating chamber or in proximity to a plasma-generating chamber such that the ions and/or radicals can reach the photoresist material. The plasma-generating chamber may comprise any suitable plasma reactor, such as an inductively coupled plasma (ICP) reactor, a transformer-coupled plasma (TCP) reactor, or a capacitively-coupled plasma (CCP) reactor. Such reactors can be configured with appropriate techniques and equipment known in the art. Dry development using plasmas is described further above along with a summary of suitable compounds for plasma generation.

While the organotin compositions described herein can generally be patterned with solutions for negative or positive patterning, the focus here is on negative patterning. Useful developer compositions for these organotin oxide photoresists have been described in published U.S. Patent Application No. 2020/0326627 to Jiang et al., entitled “Organometallic Photoresist Developer Compositions and Processing Methods”, incorporated here by reference. In general, when an organic solvent is used as a developer then negative tone patterning is realized wherein the unexposed material is dissolved away and the exposed material remains.

On particular, for the negative tone imaging, the developer can comprise an organic solvent, such as the solvents used to form the precursor solutions. In general, selection of appropriate developer solvent compositions can be influenced by solubility parameters with respect to the coating material, both irradiated and non-irradiated, as well as developer volatility, flammability, toxicity, viscosity, and potential chemical interactions with other process material. In particular, suitable developer solvents include, for example, aromatic compounds (e.g., benzene, xylenes, toluene), esters (e.g., propylene glycol monomethyl ester acetate, ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. The development can be performed for about 5 seconds to about 30 minutes, in further embodiments from about 8 seconds to about minutes and in addition embodiments from about 10 seconds to about 10 minutes. A person of ordinary skill in the art will recognize that additional ranges within the explicit ranges above are contemplated and are within the present disclosure.

During an initial development, a substantial amount of material is removed from the substrate based on the above discussions, such as in a negative tone or positive tone development process. In some cases, however, an initial development process can yield patterns having undesirably high line-width roughness (LWR) and/or defects, such as scum, residues, microbridges, and the like, remaining on the substrate due to incomplete development, material inhomogeneity, and stochastic effects, for example. In some embodiments, it can therefore be desirable to conduct a further process, such as a liquid, thermal or plasma process, to remove the unwanted material, which may be more susceptible to development chemistries comprising contrast enhancer compositions described herein. In the context of FIGS. 1-3 above, the use of contrast enhancers for pattern improvement is discussed in various process flows. Thus, the delivery of contrast enhancer and thermal development or other subsequent development of the contrast enhancer modified coating can be applied to an initially developed pattern for pattern improvement. All of the process options described above for the use of contrast enhancers can be similarly applied in the context of an initially developed substrate.

Alternatively or additionally, in some embodiments, a subsequent development step or rinse step comprising a liquid chemical can be desirable to remove unwanted material. For example, after performing a development step with a contrast enhancer, such as a dry development step (thermal or plasma), a negative tone liquid developer can be provided, such as a suitable organic solvent. In addition, it has been discovered that a rinse step can be effective for significant reduction in defect rate. The rinse step can comprise treatment with, for example, an aqueous alkaline solution to remove partially irradiated materials as well as edges of the pattern.

In the above discussion, one of ordinary skill in the art will understand that the terms substrate and wafer should be construed as generally used in the art. As understood in the art, a “substrate” itself can be structured with multiple layers, in which at least some of the layers may be patterned, and the formation of devices can comprise multiple sequential lithography steps to build up layered patterned structures. For a particular lithography step, the prior processed structure becomes the substrate for that process step. The embodiments above are intended to be illustrative and not limiting. Additional embodiments are within the scope of the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. As would be understood by a person of ordinary skill in the art, the use of the term “about” herein refers to measurement error for the particular parameter unless explicitly indicated otherwise.

### Post Development Processing

Following development of the photoresist to form a patterned coating material, along with any optional pattern improvement steps, a subsequent anneal can be performed to further solidify and stabilize the patterned features. As with other processing steps, this anneal can be performed in an environment having specific reactive gases at specific concentrations. It may be desirable for reactive gases to be present at this anneal that were not present in previous steps. Since radiation patterning has already been performed, the photosensitivity of the material need not be retained and the material can instead be converted into a new composition to facilitate further processing, such as etch. For example, reductive reactive gases such as carbon monoxide, hydrogen gas, methane, and the like, and mixtures thereof, can be present during this anneal to convert at least a portion of the material to a new composition. A reactive gas present during this anneal step can enable subsequent etch steps or other processing by converting at least a portion of the patterned material to a new composition. In this way it is possible to enable post-processing techniques that can lessen or mitigate scumming, microbridging or other defect by tailoring subsequent etch or other process steps to interact with the compositions formed by reacting the patterned material with a reactive gas. Post development heat processing with a reactive gas is described further in the '170 application cited above.

Temperatures for this anneal are not particularly limited in so far as ancillary layers or materials can retain their respective properties, such as a sufficient etch contrast, and insofar the reactivity of the selected reactive gas or gases is sufficient. In some embodiments, the anneal can be between 100° C. and 500° C., in other embodiments from 200° C. to 500° C., and from 300° C. to 400° C. in further embodiments. A person of ordinary skill in the art will recognize that additional ranges of temperature within the explicit ranges above are contemplated and are within the present disclosure.

To help evaluate the development, wafers can be patterned to evaluate pattern formation as a function of EUV dose. To first order, imaging is considered a step function of regions of illumination and non-illuminated regions. The patterned structures can be evaluated using automated imaging equipment and scanning electron microscope imagers are generally used. For example, specific commercial CD-SEM instruments can measure critical line dimensions (line widths) and can also evaluate defects, such as microbridging. In some embodiments, the improved processing described herein can result in an increase in critical dimension using the equivalent development, coating formation and irradiation. In some embodiments, the increase in critical dimension can be at least about 0.25 nm, in further embodiments at least about 0.50 nm, in further embodiments at least about 0.75 nm. A person of ordinary skill in the art will recognize that additional ranges of critical dimension increase within the explicit ranges above are contemplated and are within the present disclosure. Viewed another way, the concept of critical dimension can be expressed as a dose-to-size value, which is the radiation doze used to obtain a specific feature size. So an increase in critical dimension corresponds with a decrease in the dose-to-size value.

After forming a patterned coating material, the coating material can be further processed to facilitate formation of the selected devices. Furthermore, further material deposition, etching and/or patterning generally can be performed to complete structures. The coating material may or may not ultimately be removed. The quality of the patterned coating material can in any case be carried forward for the formation of improved devices, such as devices with smaller footprints and the like. If the layer is not removed, the patterned coating (resist) material is incorporated into the structure. For embodiments in which the patterned coating (resist) material is incorporated into the structure, the properties of the coating (resist) material can be selected to provide for desired patterning properties as well as also for the properties of the material within the structure.

### EXAMPLES

### Example: Dry Development of an Organotin Photoresist with a Reactive Vapor

This example illustrates the effectiveness of developing an organotin photoresist with a carboxylic acid vapor. This example also demonstrates the effect that various processing conditions can have on contrast enhancement.

General Coating and Processing Steps

Silicon wafers having a 10 nm layer of spin-on-glass (SOG) were used as the substrates. An organotin resist composition was deposited onto each wafer via spin coating at 1394 rpm to give a layer having a thickness of approximately 15 nm, as measured by ellipsometry. The organotin resist composition used in this example was YATU1011, manufactured by Inpria Corporation and having a composition as described in the '618 patent cited above. The coated wafers were baked at 100° C. for 60 seconds. The wafers were then exposed to KrF radiation in a chamber at a dose of 50 mJ/cm² using open-frame exposure conditions to form a set of wafer samples having a radiation patterned layer on the surface of the wafer, the radiation patterned layer having irradiated regions and non-irradiated regions. Selected wafer samples were further subjected to an additional bake at 200° C. for 90 seconds as a post-exposure bake.

Processing with a Acetic Acid Vapor

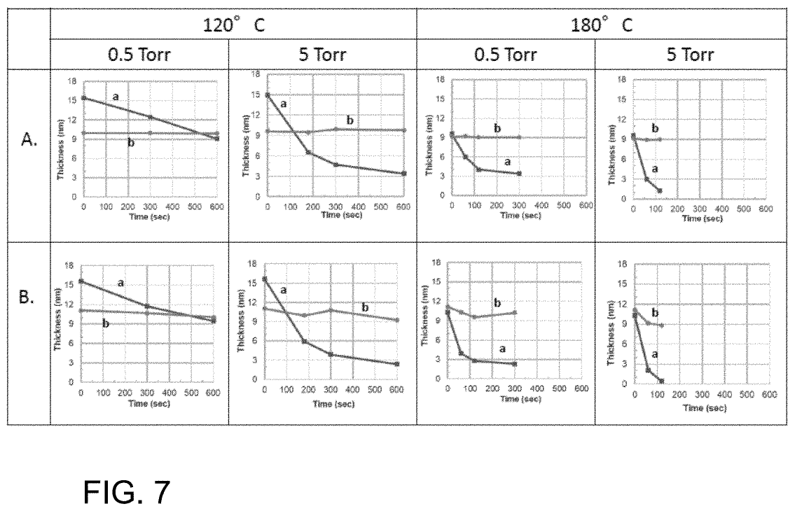

Each wafer sample was exposed to acetic acid vapor using an apparatus similar to one described above and illustrated in FIG. 4. Each wafer sample 320 was mounted on wafer stage 318 within chamber 314, configured to deliver a flow of developer gas 312 to the wafer surface. Wafer samples having been subjected to the additional bake (set A in FIG. 7) and not subjected to the additional bake (set B in FIG. 7) were processed under acetic acid vapor atmospheres with differing chamber pressure and wafer temperature conditions. Vapor flow rates of acetic acid were adjusted from values between 5 and 10 sccm (standard cubic centimeters per minute) to provide a measured chamber pressure of either about 0.5 torr or about 5 torr. The wafer samples were heated to a temperature of either 120° C. or 180° C. The heated wafer samples were exposed to the flowing acetic acid vapor for various times ranging from 0 seconds to 600s. Following the selected processing conditions with the acetic acid vapor, ellipsometry was performed to measure the film thickness of irradiated and non-irradiated regions of each wafer sample.

FIG. 7 shows the film thickness as a function of time for the non-irradiated regions of each wafer sample (labeled as “a”) and for the irradiated regions of each wafer sample (labeled as “b”). Processing with a wafer temperature of 120° C. resulted in the irradiated regions (“b”) being generally thinner than the non-irradiated regions (“a”) prior to contact with the acetic acid vapor (e.g., at t=0). This difference in initial thickness between non-irradiated and irradiated regions is attributed to loss of organic content caused by radiation-induced cleavage of Sn—C bonds, described further in the U.S. patent Ser. No. 10/732,505 to Meyers et al., entitled “Organotin Oxide Hydroxide Patterning Compositions, Precursors, And Patterning,” incorporated herein by reference. FIG. 7 also shows that the initial thickness of the non-irradiated regions (“a”) of the wafer samples heated at 180° C. were smaller than the initial thickness of the non-irradiated regions (“a”) of the wafer samples heated at 120° C. This difference is attributed to temperature-induced pre-shrinking of the non-irradiated layer.

As shown in FIG. 7, higher chamber pressure (i.e., higher flow rates of acetic acid vapor) resulted in improved removal of non-irradiated material. For example, in Set A at 180° C., the thickness of the non-irradiated material was reduced to about 1 nm at 125 seconds with 5 Torr of chamber pressure versus about 4 nm with 0.5 Torr of chamber pressure. Independently, higher wafer temperature resulted in improved removal of non-irradiated material. For example, in Set A at 5 Torr, the thickness of the non-irradiated material was reduced to about 1 nm at 125 seconds with a wafer temperature of 180° C. versus about 9 nm with a wafer temperature of 120° C. Comparing Set A to Set B, the additional high temperature post-exposure bake provided to the Set A wafer samples seems to have improved the stability of the irradiated regions based on the thickness of the irradiated regions being relatively constant over the duration of the testing. In contrast the thickness of the Set B wafer samples generally decreased slightly during the duration of the testing. Coupling of higher chamber pressure and higher wafer temperature, resulted in the most rapid selective removal of non-irradiated material. For example, at 5 Torr and 180° C., the thickness of the non-irradiated material was reduced from about 9 nm to about 1 nm in about 125 seconds (in Set A) and from about 10.5 nm to about 0.5 nm in about 125 seconds (in Set B).

This example shows that exposure of the wafer samples to acetic acid vapor can result in selective removal of non-irradiated material as a function of time for successful thermal pattern development. The results are consistent with the negative-tone development behavior seen in liquid development processes using carboxylic acid compositions. The results suggests that vapor-based development, rinsing, and/or contrast enhancement of patterned organometallic resists can lead to improved processing relative to standard processing, including the ability to finely tune the processing by adjustment of temperature, pressure, and vapor composition.

### FURTHER INVENTIVE CONCEPTS

1. A method for modifying a radiation sensitive organometallic composition on a substrate surface with a latent image formed by respective irradiated and non-irradiated portions,

the method comprising contacting the organometallic composition with a vapor of a carboxylic acid in an isolation chamber at a partial pressure from about 0.1 Torr to about 50 Torr and/or with a flow rate from about 1 sccm to about 5000 sccm, at a temperature from about −45° C. to about 250° C. to remove a relative amount of the non-irradiated portion ((initial nonirradiated thickness-final non-irradiated thickness)/initial non-irradiated thickness) wherein the relative amount of the non-irradiated portion removed is at least about 10%, while a relative amount of thickness of the irradiated portion removed ((initial irradiated thickness-final irradiated thickness)/initial irradiated thickness) is no more than one third of the relative amount of non-irradiated portion removed.

2. The method of inventive concept 1 wherein the non-irradiated portions comprise Sn—C bonds.
3. The method of inventive concept 1 wherein the organometallic composition comprises a composition represented by the formula RzSnO_{(2-z/2-x/2)}(OH)ₓ, where 0<x<3, 0<z≤2, x+z≤4,

wherein R is a hydrocarbyl or organo group with 1-31 carbon atoms, with a carbon atom bonded to Sn and with one or more carbon atoms optionally substituted with one or more heteroatom functional groups.

4. The method of inventive concept 1 wherein the carboxylic acid comprises compounds with alkyl chains having 1 to 10 carbon atoms, isomers thereof, halogenated derivatives thereof, and/or amide derivatives of thereof.
5. The method of inventive concept 1 wherein the carboxylic acid comprises formic acid, acetic acid, propionic acid, butyric acid, isobutyric acid, benzoic acid, formamide, N-methylformamide, acetamide, urea, propanamide, butyramide, isobutyramide, and combinations thereof.
6. The method of inventive concept 1 wherein the carboxylic acid comprises acetic acid.
7. The method of inventive concept 1 wherein the organometallic composition comprises an oxo-hydroxo network.
8. The method of inventive concept 1 wherein contacting results in a release of volatile species from the organometallic composition.
9. The method of inventive concept 1 wherein the method results in removal of from 10% to about 90% of the non-irradiated portion.
10. The method of inventive concept 1 wherein the non-irradiated portion is essentially completely removed after contacting the organometallic composition.
11. The method of inventive concept 1 wherein contacting is performed for about 10 seconds to about 15 minutes and wherein the flow rate is from about 1 sccm to about 5000 sccm.
12. The method of inventive concept 1 wherein contacting is performed at a chamber pressure from about 0.001 Torr to about 10 Torr, with a flow rate of at least one gas from about 1 to about 5000 sccm, for at least about 10 seconds.
13. The method of inventive concept 1 further comprising, prior to contacting, heating the organometallic composition at a temperature of about 45° C. to about 300° C. for at least about 0.1 minutes and/or aging the radiation sensitive organometallic composition for at least about 10 minutes.
14. A method for improving the quality of a patterned structure with a negative pattern corresponding to an irradiated organometallic composition on a substrate surface with non-irradiated organometallic composition substantially removed or with a positive pattern corresponding to non-irradiated organometallic composition on a substrate surface with the irradiated organometallic composition substantially removed, the method comprising:

developing a pattern from a latent image formed by irradiating a radiation sensitive organometallic composition on a substrate surface to form a patterned structure; and

following completion of the development step, contacting the patterned structure with a reactant gas in an isolated chamber to remove scum from the pattern, wherein the reactant gas is selected from water, a carboxylic acid, an amide, a sulfonic acid, alcohol, diol, silyl halide, germanium halide, tin halide, amine, thiol, a hydrogen halide or mixtures thereof.

15. The method of inventive concept 14 wherein the patterned material comprises Sn—C and/or Sn—O bonds.
16. The method of inventive concept 14 wherein the scum comprises incompletely removed non-irradiated organometallic composition associated with a negative pattern, incompletely removed irradiated organometallic composition associated with a positive pattern, partially irradiated organometallic composition, or mixtures thereof.
17. The method of inventive concept 14 wherein the scum comprises microbridges.
18. The method of inventive concept 14 wherein contacting results in altering the composition of the scum to release of volatile species from the scum.
19. The method of inventive concept 14 wherein the reactant gas comprises compounds having 1 to 10 carbon atoms.
20. The method of inventive concept 14 wherein the reactant gas comprises formamide, N-methylformamide, acetamide, urea, propanamide, butyramide, isobutyramide, methanesulfonic acid, ethanesulfonic acid, propanesulfonic acid, benzenesulfonic acid, p-toluenesulfonic acid, methanol, ethanol, n-propanol, iso-propanol, 1-butanol, iso-butanol, tert-butanol, 1-pentanol, 4-methyl-2-pentanol, cyclopentanol, 1-hexanol, cyclohexanol, phenol, methanethiol, ethanethiol, propanethiol, isopropanethiol, butyrothiol, isobutyrothiol, tert-butylthiol, methylene glycol, ethylene glycol, diethylene glycol, propylene glycol, dipropylene glycol, cyclohexanediol, trimethylsilyl chloride, trimethylsilyl bromide, dimethylsilyl chloride, dimethylsilyl bromide, monomethylsilyl chloride, monomethylsilyl bromide, tetrachlorosilane, tetrabromosilane, and combinations thereof.
21. The method of inventive concept 14 wherein contacting is performed at a temperature of about −45° C. to about 350° C. and at a chamber pressure of at least about 0.001 Torr for at least about 3 seconds.
22. The method of inventive concept 14 wherein contacting is performed with a plurality of reactant gases used simultaneously or in series.
23. A method for dry developing a radiation sensitive organometallic composition having a radiation-patterned latent image on a substrate, the method comprising:

contacting the composition having the latent image with a reactant gas to remove a substantial portion of the non-irradiated regions of the coating, wherein the non-irradiated regions of the coating comprise Sn—C bonds, and the reactant gas comprises an amide, a sulfonic acid, alcohol, diol, silyl halide, germanium halide, tin halide, amine, thiol, or mixtures thereof.

24. The method of inventive concept 23 wherein the non-irradiated regions of the coating comprise Sn—C bonds, and the reactant gas comprises a mixture of at least two gases selected from a carboxylic acid, an amide, a sulfonic acid, an alcohol, a diol, a silyl halide, a germanium halide, a tin halide, an amine, or a thiol.
25. The method of inventive concept 23 wherein the non-irradiated regions of the coating comprise Sn—C bonds, and the reactant gas comprises a mixture of at least two carboxylic acids, at least two amides, at least two sulfonic acids, at least two alcohols, at least two diols, at least two silyl halides, at least two germanium halides, at least two tin halides, at least two amines, or at least two thiols.
26. The method of inventive concept 23 wherein the composition comprises a composition represented by the formula RzSnO_{(2-z/2-x/2)}(OH)ₓ, where 0<x<3, 0<z≤2, x+z≤4,

wherein R is a hydrocarbyl or organo group with 1-31 carbon atoms, with a carbon atom bonded to Sn and with one or more carbon atoms optionally substituted with one or more heteroatom functional groups.

27. The method of inventive concept 23 wherein the reactant gas comprises compounds having 1 to 10 carbon atoms, optionally substituted with one or more heteroatom functional groups.
28. The method of inventive concept 23 wherein the reactant gas comprises formamide, N-methylformamide, acetamide, urea, propanamide, butyramide, isobutyramide, methanesulfonic acid, ethanesulfonic acid, propanesulfonic acid, benzenesulfonic acid, p-toluenesulfonic acid, methanol, ethanol, n-propanol, iso-propanol, 1-butanol, iso-butanol, tert-butanol, 1-pentanol, 4-methyl-2-pentanol, cyclopentanol, 1-hexanol, cyclohexanol, phenol, methanethiol, ethanethiol, propanethiol, isopropanethiol, butyrothiol, isobutyrothiol, tert-butylthiol, methylene glycol, ethylene glycol, diethylene glycol, propylene glycol, dipropylene glycol, cyclohexanediol, trimethylsilyl chloride, trimethylsilyl bromide, dimethylsilyl chloride, dimethylsilyl bromide, monomethylsilyl chloride, monomethylsilyl bromide, tetrachlorosilane, tetrabromosilane, and combinations thereof.
29. The method of inventive concept 23 wherein the reactant gas further comprises water.
30. The method of inventive concept 23 wherein contacting results in breaking of Sn—O—Sn and/or Sn—OH bonds in the non-irradiated regions of the coating.
31. The method of inventive concept 23 wherein contacting results in a release of volatile species from the composition.
32. The method of inventive concept 23 wherein contacting is performed with a flow rate of the reactant gas from about 1 sccm to about 5000 sccm.
33. The method of inventive concept 23 wherein contacting is performed for about 3 seconds to about 15 minutes.
34. The method of inventive concept 23 wherein contacting is performed in an isolated chamber at a pressure of about 0.001 Torr to about 50 Torr.
35. The method of inventive concept 34 wherein the pressure is adjusted by varying a flow rate of the reactant gas into the isolated chamber.
36. The method of inventive concept 34 wherein contacting is performed at temperature from about −45° C. to about 350° C.
37. The method of inventive concept 34 further comprising, prior to contacting, heating the organometallic composition at a temperature of about 45° C. to about 300° C. for at least about 0.1 minutes and/or aging the organometallic composition for at least about 10 minutes.
38. A method for developing a radiation sensitive organometallic composition having a radiation-patterned latent image on a substrate, the method comprising:

contacting the radiation patterned material with a first reactant gas composition to modify the non-irradiated regions of the coating, wherein the non-irradiated regions of the coating comprise Sn—C bonds, and the first reactant gas composition comprises a carboxylic acid, an amide, a sulfonic acid, an alcohol, a diol, a silyl halide, a germanium halide, a tin halide, an amine, a thiol, or a mixture thereof, to form an initial pattern; and,

contacting the initial pattern with a second reactant gas composition different from the first reactant gas composition to remove a portion of the initial pattern, wherein the second reactant gas composition comprises a carboxylic acid, an amide, a sulfonic acid, an alcohol, a diol, a silyl halide, a germanium halide, a tin halide, an amine, a thiol, or a mixture thereof.

39. The method of inventive concept 38 wherein contacting the initial pattern with a second reactant gas substantially removes the non-irradiated regions of the coating to form a developed pattern.
40. The method of inventive concept 38 further comprising, prior to contacting the initial pattern with a second reactant gas composition, heating the initial pattern prior at a temperature of about 45° C. to about 300° C. for at least about 0.1 minutes and/or aging the initial pattern for at least about 10 minutes.
41. The method of inventive concept 38 wherein the first and/or second reactant gas further comprises water.
42. The method of inventive concept 38 wherein the composition comprises a composition represented by the formula RzSnO_{(2-z/2-x/2)}(OH)ₓ, where 0<x<3, 0<z≤2, x+z≤4,

wherein R is a hydrocarbyl or organo group with 1-31 carbon atoms, with a carbon atom bonded to Sn and with one or more carbon atoms optionally substituted with one or more heteroatom functional groups.

43. The method of inventive concept 42 wherein contacting with the first and/or second reactant gas results in breaking of Sn—O—Sn and/or Sn—OH bonds in the non-irradiated regions of the coating.
44. The method of inventive concept 38 wherein the first and/or second reactant gas comprises a fluorinated carboxylic acid and/or a fluorinated alcohol.
45. An apparatus comprising:

an enclosed chamber;

a substrate support within the enclosed chamber, wherein the substrate support is configured to spin a substrate;

a gas supply subsystem comprising a gas source reservoir, a gas spray dispenser having a pluralities of openings distributed to provide gas dispensing directed toward a substrate mounted on the substrate support and over the extent of the substrate surface, a gas flow controller, and gas conduits connecting the gas source reservoir and the gas spray dispenser with the flow through the conduits moderated by the gas flow controller;

a liquid supply subsystem comprising a liquid reservoir, a nozzle, a nozzle support with a translatable arm for positioning the nozzle, a flow controller and tubing providing flow channels between the liquid reservoir and the nozzle, wherein the nozzle support has a configuration to configure the nozzle to deposit liquid on a substrate mounted on the substrate support;

one or more exhausts exiting the chamber; and

a pump.

46. The apparatus of inventive concept 45 further comprising a controller interfaced with a motor of the substrate support to control spinning of the substrate, the gas supply subsystem to control gas flow and liquid supply subsystem to control delivery of liquid from the liquid supply subsystem.
47. The apparatus of inventive concept 45 wherein the gas source reservoir comprises a first reservoir of a first contrast enhancing agent comprising a carboxylic acid, an amide, a sulfonic acid, an alcohol, a diol, a silyl halide, a germanium halide, a tin halide, an amine, a thiol, or a mixture thereof.
48. The apparatus of inventive concept 47 wherein the gas source reservoir further comprises an inert gas supply.
49. The apparatus of inventive concept 47 wherein the contrast enhancing agent is a liquid in the reservoir and wherein the gas supply subsystem is configured for delivery of the contrast enhancing agent as a vapor through a mass flow controller.
50. The apparatus of inventive concept 47 wherein the gas source reservoir further comprises a second reservoir of a second contrast enhancing agent.
51. The apparatus of inventive concept 45 wherein the liquid reservoir comprises a developing liquid.
52. The apparatus of inventive concept 51 wherein the developing liquid comprises an organic liquid.
53. The apparatus of inventive concept 51 wherein the developing liquid comprises an aqueous liquid.
54. The apparatus of inventive concept 45 further comprising one or more heating elements configured to heat, a substrate, the chamber, a reservoir, flow lines, gas/vapor or combinations thereof.
55. The apparatus of inventive concept 45 wherein the actuator arm can move the nozzle out of the path of flow from the gas spray dispenser.
56. The apparatus of inventive concept 45 configured with a pump having sufficient pumping capacity for the gas dispensing subsystem and the liquid dispensing subsystem to operate at pressures from 0.001 Torr to atmospheric pressure.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. A method for enhancing development contrast between irradiated and non-irradiated portions of a radiation sensitive organometallic composition on a substrate surface with a latent image, the method comprising:
contacting the organometallic composition with a reactant gas in an isolated chamber to alter the composition of the irradiated portion, the non-irradiated portion or both, wherein the reactant gas comprises an amide, a sulfonic acid, alcohol, diol, silyl halide, germanium halide, tin halide, amine, or mixtures thereof.

2. The method of claim 1 wherein the non-irradiated portions comprise Sn—C bonds.

3. The method of claim 1 wherein the organometallic composition comprises a composition represented by the formula R_{z}SnO_{(2-z/2-x/2)}(OH)ₓ, where 0<x<3, 0<z≤2, x+z≤4,
wherein R is a hydrocarbyl or organo group with 1-31 carbon atoms, with a carbon atom bonded to Sn and with one or more carbon atoms optionally substituted with one or more heteroatom functional groups.

4. The method of claim 1 wherein the organometallic composition comprises an oxo-hydroxo network.

5. The method of claim 1 wherein the reactant gas comprises a compound having 1 to 10 carbon atoms.

6. The method of claim 1 wherein the reactant gas comprises formamide, N-methylformamide, acetamide, urea, propanamide, butyramide, isobutyramide, methanesulfonic acid, ethanesulfonic acid, propanesulfonic acid, benzenesulfonic acid, p-toluenesulfonic acid, methanol, ethanol, n-propanol, iso-propanol, 1-butanol, iso-butanol, tert-butanol, 1-pentanol, 4-methyl-2-pentanol, cyclopentanol, 1-hexanol, cyclohexanol, phenol, methanethiol, ethanethiol, propanethiol, isopropanethiol, butyrothiol, isobutyrothiol, tert-butylthiol, methylene glycol, ethylene glycol, diethylene glycol, propylene glycol, dipropylene glycol, cyclohexanediol, trimethylsilyl chloride, trimethylsilyl bromide, dimethylsilyl chloride, dimethylsilyl bromide, monomethylsilyl chloride, monomethylsilyl bromide, tetrachlorosilane, tetrabromosilane, and combinations thereof.

7. The method of claim 1 wherein the reactant gas further comprises water.

8. The method of claim 1 wherein contacting results in breaking of M-O-M and/or M-OH bonds in the organometallic composition.

9. The method of claim 1 wherein contacting results in a release of volatile tin-comprising species from the organometallic composition.

10. The method of claim 1 wherein the non-irradiated portion has an initial thickness and wherein contacting results in the non-irradiated portion having an adjusted thickness, wherein the adjusted thickness is less than the initial thickness.

11. The method of claim 10 wherein the adjusted thickness is no more than 90% of the initial thickness.

12. The method of claim 10 wherein the adjusted thickness is no more than 50% of the initial thickness.

13. The method of claim 1 wherein the non-irradiated portion is essentially completely removed after contacting for no more than 10 minutes to form a developed structure.

14. The method of claim 13 further comprising processing the developed structure to improve the pattern using a liquid rinse and/or a pattern improving reactive gas.

15. The method of claim 14 wherein the pattern improving reactive gas comprises water, a carboxylic acid, an amide, a sulfonic acid, an alcohol, a diol, a silyl halide, a hydrogen halide, a germanium halide, a tin halide, an amine, or mixtures thereof.

16. The method of claim 1 wherein the substrate comprises a semiconductor wafer.

17. The method of claim 1 wherein contacting is performed with a reactant gas having a selected flow rate.

18. The method of claim 17 wherein the selected flow rate is from about 1 standard cubic centimeters per minute (sccm) to about 1000 sccm.

19. The method of claim 18 wherein an inert gas flow rate is from about 0.5 standard liters per minute (SLM) to about 30 SLM.

20. The method of claim 19 wherein the contacting is performed at a chamber pressure from about 100 Torr to about 1200 Torr.

21. The method of claim 1 wherein contacting is performed for about 3 seconds to about 15 minutes.

22. The method of claim 1 wherein contacting is performed at a chamber pressure of about 0.001 Torr to about 10 Torr.

23. The method of claim 1 wherein the chamber pressure is adjusted by varying the flow rate of gas into the isolated chamber, and wherein the chamber pressure may change over the course of a period of the contacting.

24. The method of claim 1 wherein the substrate, the reactant gas, and/or the isolated chamber are at a temperature from about −45° C. to about 350° C. during contacting.

25. The method of claim 1 wherein contacting is performed at a temperature of about 100° C. to about 250° C. and at a chamber pressure of at least about 0.1 Torr for at least about 10 seconds.

26. The method of claim 1 wherein contacting is performed prior to a development process.

27. The method of claim 1 wherein contacting is performed after a development process.

28. The method of claim 27 wherein the development process is a liquid based development process.

29. The method of claim 27 wherein the development process is a dry development process performed with a developing reactive gas or with a plasma.

30. The method of claim 27 wherein the development process formed a negative pattern substantially maintaining an irradiated portion of the organometallic composition.

31. The method of claim 27 wherein the development process formed a positive pattern substantially maintaining an irradiated portion of the organometallic composition.

32. The method of claim 1 wherein contacting is performed with a plurality of reactant gases used simultaneously or in series.

33. The method of claim 1 further comprising, prior to contacting, heating the organometallic composition at a temperature of about 45° C. to about 300° C. for at least about 0.1 minutes and/or aging the organometallic composition for at least about 10 minutes.
